(19) United States
(12) Patent Application Publication
(10) Pub. No.: US 2012/0056194 A1
(43) Pub. Date: Mar. 8, 2012

(54) BARRIER STRUCTURES AND METHODS OF FORMING SAME TO FACILITATE SILICON CARBIDE EPITAXY AND SILICON CARBIDE-BASED MEMORY FABRICATION

(75) Inventors: Sima Dimitrijev, Shailer Park (AU); Li Wang, Berrinba (AU); Jisheng Han, Calamvale (AU); Alan Iacopi, Thornlands (AU); Leonie Hold, Sadliers Crossing (AU); Philip Tanner, The Gap (AU); Fred Kong, Kuraby (AU); Herbert Barry Harrison, Caloundra (AU)

(73) Assignee: Qs Semiconductor Australia Pty Ltd, East Melbourne (AU)

(21) Appl. No.: 12/876,028

(22) Filed: Sep. 3, 2010

(51) Int. Cl. H01L 29/24; H01L 21/20

(52) U.S. Cl. 257/77; 438/478; 257/E21.09; 257/E29.104

(57) ABSTRACT

Embodiments of the invention relate generally to semiconductors and semiconductor fabrication techniques, and more particularly, to devices, integrated circuits, substrates, wafers and methods to form barrier structures to facilitate formation of silicon carbide epitaxy on a substrate, such as a silicon-based substrate, for fabricating various silicon carbide-based semiconductor devices, including silicon carbide-based memory elements and cells. In some embodiments, a semiconductor wafer includes a silicon substrate, a barrier-seed layer disposed over the silicon substrate, and a silicon carbide layer formed over the barrier-seed layer. The semiconductor wafer can be used to form a variety of SiC-based semiconductor devices. In one embodiment, a silicon carbide-based memory element is formed to include barrier-seed layer, multiple silicon carbide layers formed over the barrier-seed layer, and a dielectric layer formed over the multiple silicon carbide layers.

### CROSS-REFERENCE TO RELATED APPLICATIONS

This application herein incorporates by reference, for all purposes, the following applications: U.S. patent application Ser. No. 12/543,473, filed Aug. 18, 2009 with Attorney Docket No. QSS-005 and titled “Substrates and Methods of Fabricating Epitaxial Silicon Carbide Structures with Sequential Emphasis,” U.S. patent application Ser. No. 12/543,478, filed Aug. 18, 2009 with Attorney Docket No. QSS-006 and titled “Substrates and Methods of Fabricating Doped Epitaxial Silicon Carbide Structures with Sequential Emphasis,” U.S. patent application Ser. No. 12/639,925, filed Dec. 16, 2009 with Attorney Docket No. QSS-015 and titled “Charge Retention Structures and Techniques for Implementing Charge Controlled Resistors in Memory Cells and Arrays of Memory,” and U.S. patent application Ser. No. 12/775,419, filed May 6, 2010 with Attorney Docket No. QSS-001 and titled “Substrates and Methods of Forming Film Structures to Facilitate Silicon Carbide Epitaxy.”

### FIELD

Embodiments of the invention relate generally to semiconductors and semiconductor fabrication techniques, and more particularly, to devices, integrated circuits, substrates, wafers and methods to form barrier structures to facilitate formation of silicon carbide epitaxy on a substrate, such as a silicon-based substrate, for fabricating various silicon carbide-based semiconductor devices, including silicon carbide-based memory elements and cells.

### BACKGROUND

A variety of conventional memory cells structures have been developed in various memory technologies. Silicon carbide has been identified recently as a material that can be used to manufacture structures that can store data. While silicon carbide and methods of fabricating the same have been used to fabricate conventional semiconductor devices, such as light emitting devices (“LEDs”) devices and high power switching devices, traditional techniques for fabricating silicon carbide semiconductors may not be well-suited for manufacturing non-volatile memory devices. While functional, some conventional approaches use sources of silicon or carbon that include other elements, such as hydrogen, that might contribute to formation of undesirable structures when forming a silicon carbide epitaxial layer on or over a substrate, such as a silicon substrate. The locations of some such undesirable structures or defects are typically at or near the interface between the silicon substrate and the silicon carbide layer.

In some conventional approaches of fabricating silicon carbide structures, oxygen and/or carbon contamination may influence the formation of undesirable structures. Carbon contaminants might also affect the formation of the silicon carbide epitaxial layers when uncontrolled carbon diffuses into the silicon substrate and/or distorts the silicon lattice structure of the substrate. In some cases, a source of carbon contamination might be the internal surfaces of, for example, an epitaxial reactor. The presence of uncontrolled oxygen can contribute to formation of silicon dioxide (“SiO₂”), which may interfere with reactions between a silicon substrate and a reacting gas or precursor. SiO₂ also might contribute to other defects (e.g., stacking faults) in one or more silicon carbide epitaxial layers. Therefore, common fabrication techniques performed prior to formation of the silicon carbide typically aim to exclude or minimize the inadvertent use of either carbon or oxygen (to avoid growth of SiO₂), or both.

Usually during conventional approaches of fabricating silicon carbide structures, the surface of a semiconductor substrate or wafer generally is processed prior to silicon carbide formation in an attempt to decrease the effects of contamination, including the removal of native oxide. The native oxide obscures the crystal pattern of the semiconductor substrate, and interferes with the growth of silicon carbide epitaxial layer and its orientation with the semiconductor substrate. Hydrogen annealing and vacuum annealing techniques, for example, have been used to remove a native oxide grown on the semiconductor wafer. A native oxide is usually formed on a silicon surface when exposed to an ambient environment that includes air. A drawback to these techniques is that they tend to remove oxide non-uniformly, which, in turn, might expose portions of the semiconductor surface, which can contribute to the roughness of the surface. Another drawback is that these techniques are performed generally at relatively high temperatures that are sufficient, for instance, to cause carbon to interact via exposed localized portions with the semiconductor substrate. Such diffusion can cause etch pits and distortions of the crystal lattice. The semiconductor surface is susceptible generally to etch pit formation prior to or during the initial growth of a silicon carbide epitaxial layer.

It is desirable to provide improved techniques, systems, integrated circuits, wafers, and methods that minimize one or more of the drawbacks associated with devices, integrated circuits, substrates, wafers and methods to form barrier structures that facilitate formation of silicon carbide epitaxy on a substrate, whereby the silicon carbide layers can be used to fabricate various silicon carbide-based semiconductor devices, including silicon carbide-based memory elements and cells.

### BRIEF DESCRIPTION OF THE FIGURES

The various embodiments are more fully appreciated in connection with the following detailed description taken in conjunction with the accompanying drawings, in which:

FIG. 1A is a diagram depicting an example of a semiconductor wafer fabricated to include a barrier-seed layer, according to at least some embodiments of the invention;

FIG. 1B is a diagram depicting an example of a flow to form a barrier-seed layer and one or more silicon carbide epitaxial layers using one of a number of deposition processes, including concurrent supply epitaxy, according to various embodiments;

FIG. 2 is a flow diagram depicting an example of a flow for preparing a surface of a substrate to facilitate silicon carbide deposition, according to at least some embodiments;

FIG. 3 is a flow diagram depicting an example of forming a barrier-seed layer, according to various embodiments;

FIG. 4 is a diagram depicting an example of introducing materials during the formation of a barrier-seed layer, according to various embodiments;

FIG. 5 is a flow diagram depicting an example of performing concurrent supply epitaxy, according to various embodiments;

FIG. 6 is a diagram depicting an example of introducing precursors concurrently to form a silicon carbide epitaxial layer, according to various embodiments of the invention;

FIG. 7 illustrates a system implementing a process controller that is configured to form an ultrathin oxide, activate a substrate surface, form an ultrathin carbonized film, and/or form a barrier-seed layer, according to some embodiments;

FIG. 8 illustrates an exemplary computer system suitable to form an ultrathin oxide, activate a substrate surface, form an ultrathin carbonized film, and/or form a barrier-seed layer, according to at least one embodiment;

FIGS. 9A to 9G are diagrams depicting another example of forming multiple layers of silicon carbide epitaxial layers, according to various embodiments of the invention;

FIG. 10A is a diagram depicting a silicon carbide-based structure including multiple layers of SiC, according to various embodiments of the invention;

FIG. 10B is a diagram depicting a silicon carbide-based memory element including multiple layers of SiC, according to various embodiments of the invention;

FIG. 11 is a flow diagram depicting an example of forming a silicon carbide-based memory element, according to various embodiments; and

FIGS. 12A to 12C depict the fabrication of a silicon carbide-based memory element, according to various embodiments.

Like reference numerals refer to corresponding parts throughout the several views of the drawings. Note that most of the reference numerals include one or two left-most digits that generally identify the figure that first introduces that reference number.

### DETAILED DESCRIPTION

Various embodiments or examples of the invention may be implemented in numerous ways, including as a system, a process, an apparatus, or a series of program instructions on a computer readable medium such as a computer readable storage medium or a computer network where the program instructions are sent over optical, electronic, or wireless communication links. In general, operations of disclosed processes may be performed in an arbitrary order, unless otherwise provided in the claims.

A detailed description of one or more examples is provided below along with accompanying figures. The detailed description is provided in connection with such examples, but is not limited to any particular example. The scope is limited only by the claims, and numerous alternatives, modifications, and equivalents are encompassed. Numerous specific details are set forth in the following description in order to provide a thorough understanding. These details are provided as examples and the described techniques may be practiced according to the claims without some or all of the accompanying details. For clarity, technical material that is known in the technical fields related to the examples has not been described in detail to avoid unnecessarily obscuring the description.

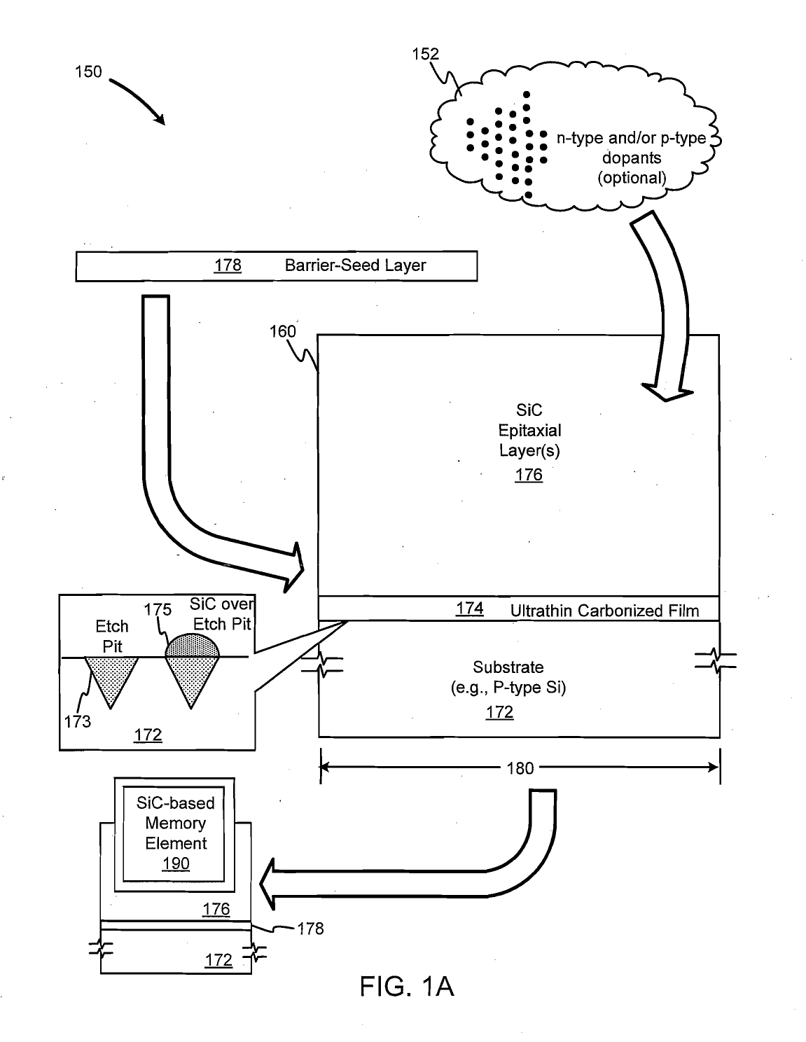

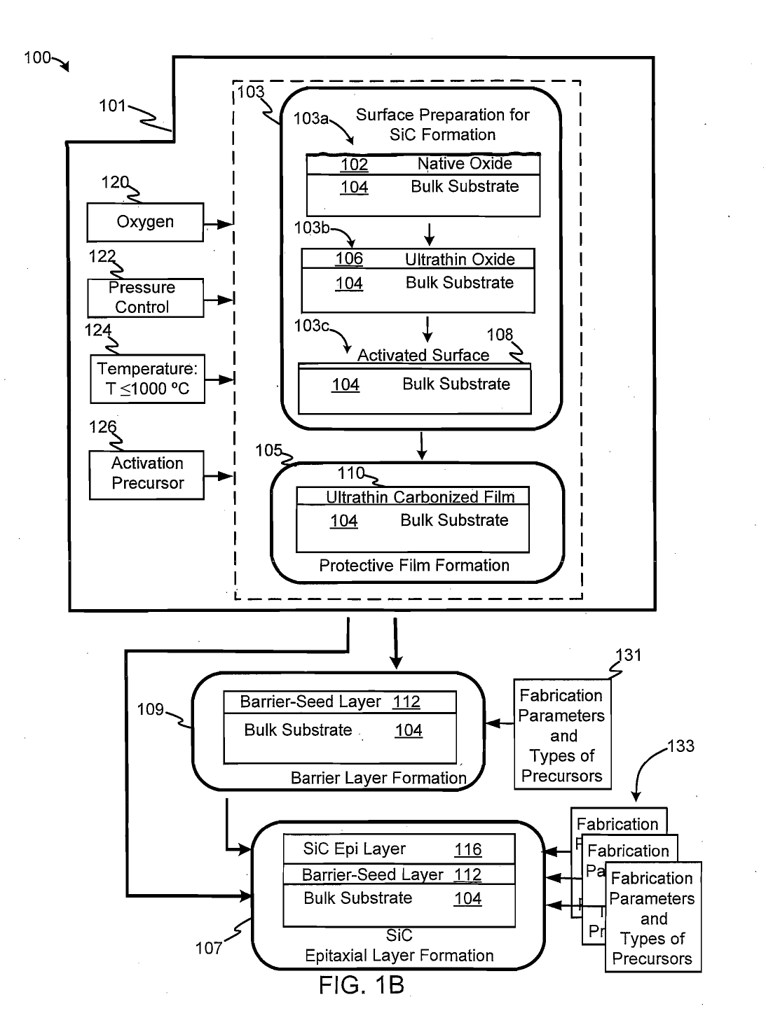

FIG. 1A is a diagram 150 depicting an example of a semiconductor wafer 160 fabricated to include a barrier-seed layer 178, according to at least some embodiments. As shown, an ultrathin carbonized film 174 is disposed on a substrate 172. In some embodiments, barrier-seed layer 178 is formed to replace ultrathin carbonized film 174 as, for example, the latter is removed during fabrication (e.g., as the temperature of ultrathin carbonized film 174 is elevated to (or near to) a temperature at which elements, such as carbon, may interact with the elements of substrate 172). One or more silicon carbide (“SiC”) epitaxial layers 176 are disposed over barrier-seed layer 178, and, though not required, can include silicon carbide epitaxial layers 176 that, for example, include either p-type or n-type dopants 152. Further to FIG. 1A, note that semiconductor wafer. 160 can be used to form many different semiconductor devices, including a silicon carbide (“SiC”)-based memory element 190 that is formed in semiconductor wafer 160.

In view of the foregoing, barrier-seed layer 178 and the processes of forming barrier-seed layer 178 can enhance the structures and/or functionalities of a wafer (i.e., a base wafer) and subsequent circuitry formed in silicon carbide upon the wafer. Further, barrier-seed layer 178 and the processes of forming barrier-seed layer 178 can facilitate forming silicon carbide epitaxial layers 176. Barrier-seed layer 178 is configured to establish a barrier to reduce contamination of elements (e.g., silicon elements) in substrate 172, such as carbon elements diffusing into substrate 172. Barrier-seed layer 178 is also configured to establish a barrier to reduce or eliminate the outdiffusion of elements from substrate 172. Thus, barrier-seed layer 178 can reduce or eliminate the formation of etch pits 173 and/or SiC-over-etch pits 175, both of which are undesirable structures. Further, barrier-seed layer 178 is configured to orient the crystalline structures of subsequently-formed silicon carbide layers 176. In some embodiments, ultrathin carbonized film 174 is configured to inhibit contaminants from interacting with elements of substrate 172 (e.g., carbon contaminants are inhibited from interacting with silicon) during, for example, an interval of time that the temperature increases to a temperature for initiating silicon carbide epitaxy. Barrier-seed layer 178 is configured to establish a barrier to reduce contaminant interactions near or at a temperature suitable for performing silicon carbide epitaxy in accordance with various embodiments. According to some embodiments, barrier-seed layer 178 is configured to also maintain the structural and/or functional integrity of other layers formed prior to formation of barrier-seed layer 178. For instance, barrier-seed layer 178 is configured to inhibit undesired reactions with a heterojunction interface layer (not shown), an example of which is described in U.S. patent application Ser. No. 12/543,478, filed Aug. 18, 2009. In accordance with some embodiments, barrier-seed layer 178 facilitates the use of different silicon carbide deposition processes. In one embodiment, barrier-seed layer 178 can be formed by, for example, concurrently introducing at least two precursors into a reaction region (not shown) that includes substrate 172, whereas silicon carbide epitaxial layers 176 can be formed with a different process.

Further, one or more of silicon carbide epitaxial layers 176 can be formed by concurrently introducing two precursors (i.e., two separate sources of elements) into the reaction region that includes substrate 172, according to various embodiments. The term “concurrent supply epitaxy” can refer, at least in some embodiments, to the introduction of two or more precursors to form a layer of silicon carbide. For example, concurrent supply epitaxy can refer to the contemporaneous introduction of a silicon-based gas and a carbon-based gas, whereby the silicon-based and carbon-based gases are introduced together and overlap for at least a portion of an interval of time during which a silicon carbide layer is formed. Note that the silicon-based and carbon-based gases can be introduced together and can overlap, in some cases, the entire interval of time during the formation of a silicon carbide layer. As such, silicon carbide epitaxial layers 176 can be used to fabricate other semiconductor devices other than memory devices, including, but not limited to light emitting devices (“LEDs”) devices and high power switching devices.

Semiconductor wafer 160 is configured to facilitate fabrication of silicon carbide-based memory elements, such as silicon carbide-based memory element 190, which is configured to store one or more states as information for a silicon carbide-based memory device. As silicon carbide, such as 3C—SiC, can have a band gap of 2.38 eV relative to 1.12 eV for silicon, silicon carbide-based memory element 190 can be configured to retain data in, for example, a nonvolatile manner. In some examples, the relatively wide energy gap of silicon carbide-based memory element 190 can retain charge longer than silicon-based memory elements, such as those used in silicon-based DRAM memory elements. In other examples, silicon carbide-based memory element 190 can provide for a forward-biased PN junction to facilitate relatively fast programming cycles compared to, for instance, silicon-based FLASH memory elements. Further, barrier-seed layer 178 and silicon carbide epitaxial layers 176 can be formed using low pressure chemical vapor deposition (“LPCVD”) processes, thereby enabling formation of silicon carbide-based memory element 190 using deposition processes that are compatible generally with CMOS fabrication techniques. Therefore, silicon carbide-based memory element 190 can be formed using a silicon carbide deposition process integrated into a CMOS fabrication process flow for forming CMOS circuitry (e.g., CMOS sense amplifier circuits, CMOS decoder circuits, etc., as well as non-memory-related CMOS circuitry).

In at least one embodiment, barrier-seed layer 178 is formed on ultrathin carbonized film 174. According to various embodiments, semiconductor wafer 160 can include intervening layers (not shown) between those shown in FIG. 1A. Semiconductor wafer 160 can have a diameter 180 of approximately 150 mm or larger, according to some embodiments. In other embodiments, semiconductor wafer 160 can be composed of any semiconductor material, such as gallium arsenide, etc. In some embodiments, semiconductor wafer 180 can be composed of either p-type or n-type semiconductor material. In at least one embodiment, barrier-seed layer 178 is formed as an n-type barrier-seed layer 178, and the n-type dopants, such as nitrogen or oxygen, can be supplied by the ambient environment. In some embodiments, barrier-seed layer 178 can have a thickness greater than 5 nm. For instance, the barrier-seed layer can be about 10 nm thick, or within a range thereabout (e.g., +/−50%). In some embodiments, an ultrathin carbonized film, such as ultrathin carbonized film 174, can be relatively thin (e.g., one or more monolayers of silicon carbide thick). For example, ultrathin carbonized film 174 can be about 2 nm, or within a range thereabout (e.g., +/−30%). Or, ultrathin carbonized film 174 can be greater than 2 nm (e.g., ultrathin carbonized film 174 can be 7 nm thick or thinner). In at least one instance, ultrathin carbonized film 174 can have a thickness ranging from one monolayer to several monolayers (e.g., three or more monolayers) of carbonized silicon. In some examples, the ultrathin carbonized film is one to two atomic layers thick. Note that in some embodiments, barrier-seed layer 178 can be referred to as a “seed epitaxial layer,” and ultrathin carbonized film 174 can be referred to as a “carbonized layer.” In a specific embodiment, barrier-seed layer 178 is optional and need not be formed for various implementations. Thus, barrier-seed layer 178 may be omitted during formation of silicon carbide epitaxial layers 176 when using concurrent supply epitaxy processes.

FIG. 1B is a diagram depicting an example of a flow to form a barrier-seed layer and one or more silicon carbide epitaxial layers using one of a number of deposition processes, including concurrent supply epitaxy, according to various embodiments. Flow 100 includes a substrate surface preparation sub-flow 101, a barrier formation sub-flow 109, and a silicon carbide (“SiC”) epitaxial layer formation sub-flow 107. Substrate surface preparation sub-flow 101 can include one or more sub-flows to adapt a substrate (e.g., the substrate surface) to facilitate silicon carbide epitaxial layer formation. Sub-flow 101 is shown to include a sub-flow 103 for preparing a substrate surface for silicon carbide epitaxial layer formation, and a sub-flow 105 for forming a protective layer (e.g., a transitory film) during transitions of fabrication parameters. Sub-flows 103 and 105 are shown to be influenced by various fabrication parameters, which, for example, can include an introduction of oxygen 120, a pressure 122 that can be controlled over a range of pressures, a temperature 124 that can be controlled over a range of temperatures, and an introduction of an activation precursor 126 (i.e., a precursor or material). An example of activation precursor 126 is silicon (e.g., in a gaseous form). Sub-flow 103 is configured to activate the surface of a bulk substrate 104. In particular, bulk substrate 104, which has a native oxide 102 grown thereupon, is introduced at 103a into sub-flow 103. At 103b, an ultrathin oxide 106 is grown on bulk substrate 104 for a first set of fabrication parameters, and can be transitory in nature. In some cases, ultrathin oxide 106 can be described as a film. Ultrathin layer of oxide 106 is configured to inhibit contaminants from interacting with bulk substrate 104. At 103c, sub-flow 101 implements a second set of fabrication parameters to activate the surface of bulk substrate 104 to form an activation surface 108. In one embodiment, sub-flows 103, 105 and 107, for example, are similar to those described in U.S. patent application Ser. No. 12/775,419, filed May 6, 2010 with Attorney Docket No. QSS-001.

Once the surface is activated, sub-flow 101 can continue to sub-flow 105, sub-flow 109, or sub-process 107. In sub-flow 105, an ultrathin carbonized film 110 is formed on bulk substrate 104 that is configured to inhibit contaminants from interacting with bulk substrate 104 as fabrication parameters are modified (e.g., to form an epitaxial layer 116 of silicon carbide). In sub-flow 109, a barrier-seed layer 112 is formed on bulk substrate 104 (or on an intervening layer) to inhibit contaminants from interacting with bulk substrate 104 as fabrication parameters are near or at values (e.g., pressure and temperature values) suitable to form an epitaxial layer 116 of silicon carbide. Examples of an intervening layer include ultrathin carbonized film 110 and a heterojunction layer, which is not shown. In some embodiments, ultrathin carbonized film 110 is configured to inhibit contaminants from interacting with substrate 104 during on portion of flow 100 (e.g., during a first interval of time) and barrier-seed layer 112 is configured to inhibit contaminants from interacting with substrate 104 during another portion of flow 100 (e.g., during a second interval of time). Ultrathin carbonized film 110 can be sufficiently sized to reduce or eliminate silicon outdiffusion from, and carbon diffusion into, bulk substrate 104 during the first interval of time, and also can be sufficiently sized to minimize delays in the formation of barrier-seed layer 112. Barrier-seed layer 112 can be sufficiently sized to reduce or eliminate silicon outdiffusion from, and carbon diffusion into, bulk substrate 104 during the second interval of time, and also can be sufficiently sized to minimize delays in the formation of silicon carbide epitaxial layer 116 in sub-flow 107. In sub-flow 107, a silicon carbide epitaxial layer 116 can be formed either using ultrathin carbonized film 110 (i.e., flow 100 moves from sub-flow 105 to sub-flow 107) or without using ultrathin carbonized film 110 (i.e., flow 100 moves from sub-flow 103 to sub-flow 107). Or, silicon carbide epitaxial layer 116 can be formed either using barrier-seed layer 112 (i.e., flow 100 moves from sub-flow 109 to sub-flow 107) or without using barrier-seed layer 112 (i.e., flow 100 moves from sub-flow 105 to sub-flow 107). Silicon carbide epitaxial layer 116 can include silicon carbide of the form 3C—SiC, as well as any other form or polytype (e.g., 4H—SiC, 6H—SiC, etc.), according to various embodiments.

In view of the foregoing, the processes of activating the surface of bulk substrate 104 and/or forming a protective film (i.e., ultrathin carbonized film 110) can enhance the structures and/or functionalities of a wafer (i.e., a base wafer) and subsequent circuitry formed in silicon carbide that is formed upon the wafer. In at least some embodiments, oxygen 120 is used deliberately to form a SiO₂ layer, such as ultrathin oxide 106, which is configured to inhibit uncontrolled interactions of contaminants (e.g., carbon) with bulk substrate 104. In some examples, bulk substrate 104 is a silicon substrate. Therefore, as a fabrication parameters changes (i.e., is modified), such as an increase in temperature, the formation of ultrathin oxide 106 can inhibit and/or reduce the interactions of carbon and silicon (e.g., partially-activated silicon) that otherwise may give rise to undesirable structures (e.g., etch pits, deformations in the silicon lattice, etc.). In some embodiments, the formation of barrier-seed layer 112 can inhibit and/or reduce the interactions of carbon and silicon that otherwise may give rise to undesirable structures, such as etch pits, deformations in the silicon lattice, and the like (e.g., during partially-activated silicon conditions when fabrication parameters are at or near those parameter values for forming silicon carbide epitaxial layers). Ultrathin oxide 106 and/or barrier-seed layer 112 also can reduce or eliminate a need to clean a chamber (e.g., a tube in an epitaxial reactor) that otherwise might be a source of carbon contaminants from previous deposition cycles. Also, the deliberate formation of a SiO₂ layer (e.g., ultrathin oxide 106) provides for a uniform (or a generally more uniform) than native oxide 102. A more uniform layer of ultrathin oxide 106 facilitates the uniform removal of the SiO₂ at 103c, which, in turn, reduces or eliminates localized exposure to the silicon substrate that otherwise interacts with carbon. Uniform removal of the SiO₂ also can provide for a more uniform or a smoother silicon surface, as well as a more uniform or smooth interface of silicon-silicon carbide. A smoother interface can minimize or eliminate defects in a silicon carbide layer that otherwise might cause leakage in semiconductor devices and circuitry formed in the silicon carbide layer.

In some embodiments, activating the surface of bulk substrate 104 can include removing ultrathin oxide 106 (and native oxide 102 over which ultrathin oxide 106 can be formed) in a uniform manner. In some examples, activation precursor 126 can include a silicon-based gas to remove ultrathin oxide 106. Further, the removal of ultrathin oxide 106 can also provide for the removal of impurities in the ultrathin oxide 106, thereby cleaning the wafer and its surface. As such, sub-process 103 can obviate a need to clean (e.g., mechanically or chemically) the surface of a wafer prior to silicon carbide formation. In at least some embodiments, ultrathin carbonized film 110 is formed below a surface activation temperature to inhibit interactions between carbon and silicon (e.g., below a temperature at which silicon and carbon interact sufficiently to form an epitaxial layer of silicon carbide for a respective pressure, and/or the temperature at which to deposit silicon carbide on the surface of the silicon substrate). Ultrathin carbonized film 110 can be dissolved, at in some cases, relatively quickly due to its thickness, which can range from a monolayer to a thickness greater than a monolayer. In at least some embodiments, oxygen 120 is used deliberately to form a SiO₂ layer, such as ultrathin oxide 106, which is configured to inhibit uncontrolled interactions of contaminants (e.g., carbon) with bulk substrate 104. In some embodiments, flow 100 uses low pressure chemical vapor deposition (“LPCVD”) techniques and parameters rather than using molecular beam epitaxy (“MBE”). In various embodiments, barrier-seed layer 112 is configured to promote the use of a variety of fabrication parameters and types of precursors 133 (i.e., different depositions processes). In at least one embodiment, the fabrication parameters and types of precursors 131 for forming barrier-seed layer 112 can be similar to a set fabrication parameters and types of precursors in the variety of fabrication parameters and types of precursors 133.

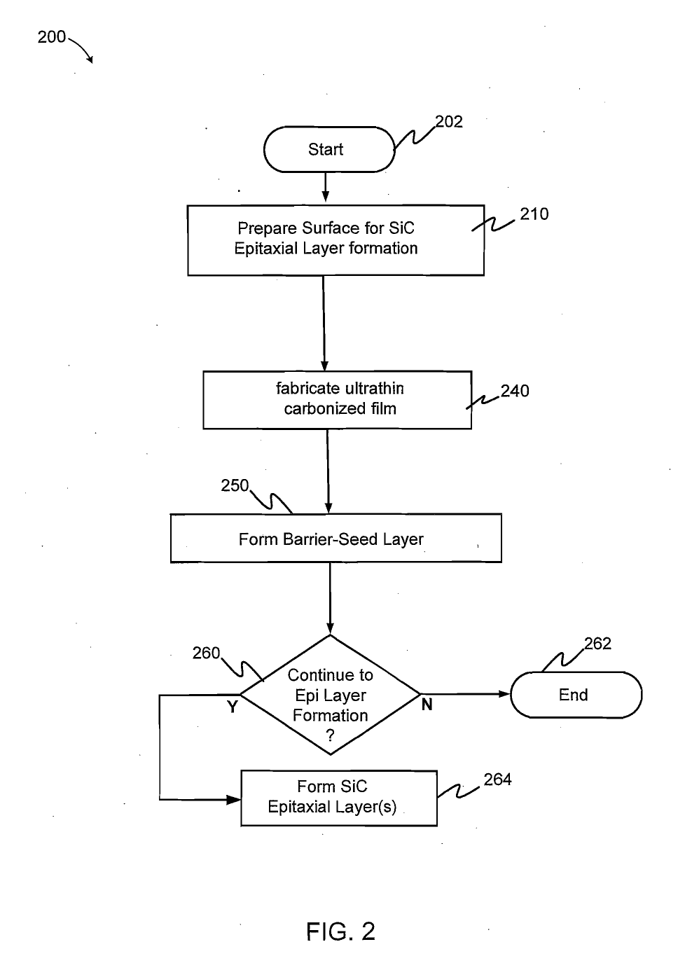

FIG. 2 is a flow diagram depicting an example of a flow for preparing a surface of a substrate to facilitate silicon carbide deposition, according to at least some embodiments. In accordance with flow 200 starting at 202, a barrier-seed layer is formed prior to silicon carbide epitaxial (“epi”) layer formation at 260. At 210, the surface of a substrate is prepared for silicon carbide epitaxial layer formation. Namely, an ultrathin oxide can be formed at temperature values and pressure values that inhibit the interactions of carbon with a silicon substrate while promoting growth of an ultrathin SiO₂ layer. Further, the temperature can be modified from an initial temperature to an ending temperature, during which the ultrathin SiO₂ layer is grown. Examples of an initial temperature include temperatures, from approximately 500° C. to approximately 670° C., or up to 750° C., and examples of an ending temperature include temperatures in the range from about 800° C. and 1,100° C. In one example, the ending temperature can be approximately 1,000° C. or 1,050° C., or any temperature in between such that the surface of the substrate is sufficiently activated. Silicon is introduced and the ultrathin SiO₂ layer is removed in accordance with, for example, the following reaction: Si(g)+SiO₂(s)=>2SiO(g). Subsequent to the removal of the last portions of the ultrathin SiO₂ layer, silicon can be deposited onto a silicon substrate surface to form an activated surface. Accordingly, the activated surface can be free of stacking faults and also can have a continuously uniform surface. At 240, an ultrathin carbonized film is formed at a carbonization temperature of approximately 750° C., according to one embodiment. In other examples, the carbonization temperature can range from 600° C. to 850° C. In some embodiments, an ultrathin carbonized film is a “transitory film,” which is a structure formed to endure from the transition of one processing step to another processing step.

At 250, a barrier-seed layer is formed. In one embodiment, the temperature of a reaction region in which a substrate is disposed is set to a temperature, Tseed, between about 800° C. and about 1,100° C., or up to 1,200° C. For example, the “seed temperature,” Tseed, can be set to approximately 1,000° C. to form the barrier-seed layer. Once the temperature is set, then two precursors are introduced concurrently or (substantially concurrently) to form a barrier-seed layer composed of silicon carbide. At 260, flow 200 diverts either to 262 or to 264 as a function of whether an epitaxial layer of silicon carbide is to be formed. If so, flow moves to 260 to perform silicon carbide epitaxy, such as concurrent supply epitaxy or any silicon carbide deposition process described in U.S. patent application Ser. No. 12/543,473, filed Aug. 18, 2009, and U.S. patent application Ser. No. 12/543,478, filed Aug. 18, 2009, as well as any other suitable silicon carbide epitaxy layer deposition process. Otherwise, flow 200 ends at 262.

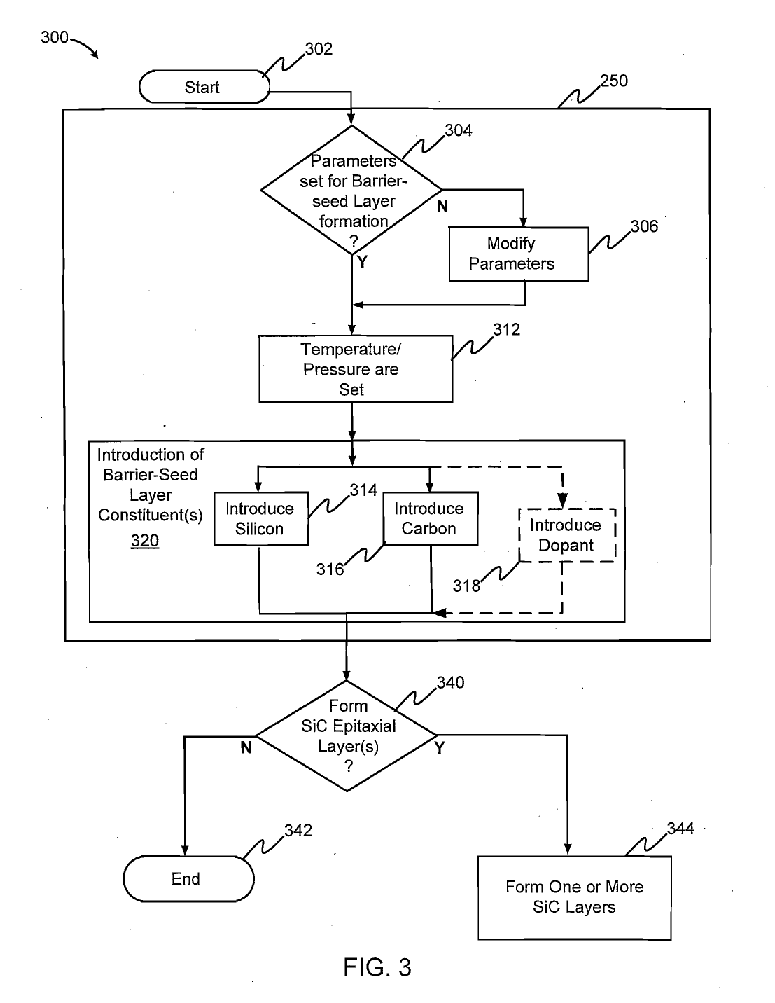

FIG. 3 is a flow diagram depicting an example of forming a barrier-seed layer, according to various embodiments. Flow 300 starts at 302. At 304, a determination is made as to whether the fabrication parameters are set for barrier-seed layer formation. If not, the fabrication parameters, such as temperature and pressure, are modified at 306. For example, if flow 300 follows the formation of an ultrathin carbonized film, then the initial temperature is at a carbonization temperature (e.g., approximately 750° C.). Thus, the temperature is modified from the carbonization temperature to the seed temperature. If the determination indicates that fabrication parameters are set at 312, then flow 300 moves to 320 at which barrier-seed layer constituent(s) are introduced concurrently as two or more precursors. In some embodiments, silicon elements are introduced at 314 as a silicon-based gas substantially concurrent with the introduction of carbon elements at 316 as a carbon-based gas. In some embodiments, the carbon-to-silicon ratio is set to approximately two, and the pressure is set to a value indicative of operation in the molecular flow regime for one or more of the precursor elements (e.g., for silicon in a gaseous state and as a silicon precursor). The barrier-seed layer can be formed in various other ways, according to various other embodiments. In some embodiments, one or more dopants can be introduced at 318, the one or more dopants including n-type dopants or p-type dopants. An example of a p-type dopant is trimethylaluminum (“(CH₃)₃Al”), or TMAl. In at least one embodiment, silicon elements can be introduced at 314 and carbon elements introduce at 316 can be introduced in different quantities during different periods of time in a cycle. In various examples, silicon elements at 314 can be introduced in alternating intervals of time with the introduction of the carbon elements at 316, or silicon elements at 314 and carbon elements at 316 can be introduced with sequential emphasis, such as set forth in U.S. patent application Ser. No. 12/543,478, filed Aug. 18, 2009. In accordance with some embodiments, a barrier-seed layer need not be limited to precursors introduced at 314 and 316. For example, the barrier layer can be formed using one precursor or more than three precursors. At 340 of flow 300, a determination is made as to whether further in-situ processing is to be performed. If processing is to continue, then flow 300 moves to 344 at which fabrication parameters are modified to facilitate the formation of one or more silicon carbide layers. Otherwise, flow 300 moves to 342 at which flow 300 ends. Note that 304 to 320 can constitute 250 of FIG. 2, according to some embodiments. In an embodiment not shown, the barrier-seed layer can be formed from a single precursor.

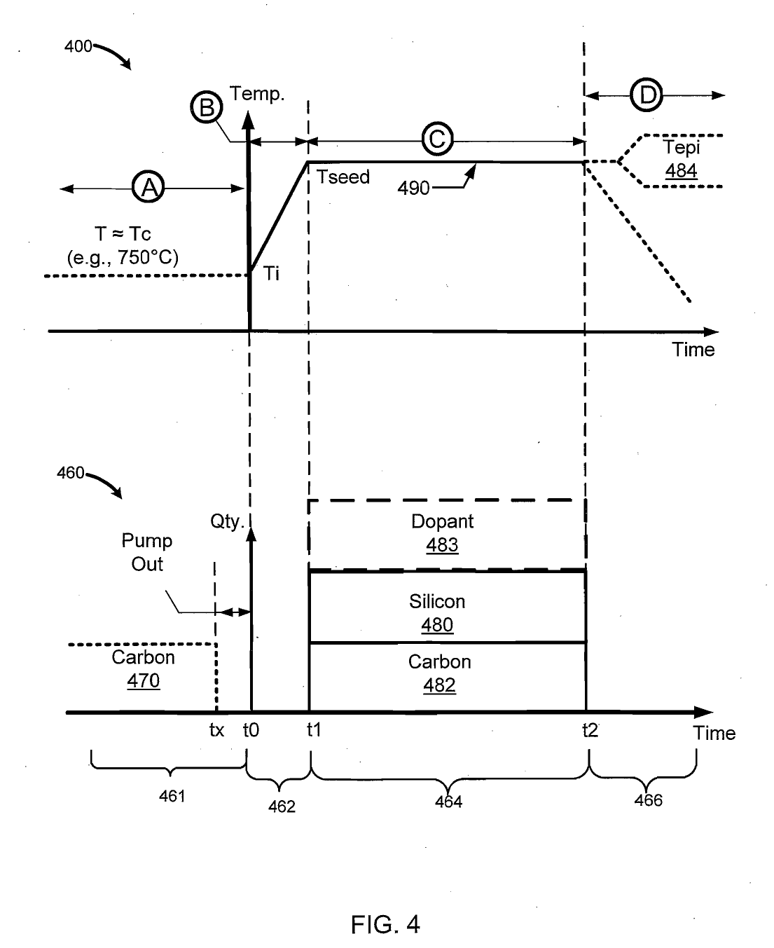

FIG. 4 is a diagram depicting an example of introducing materials during the formation of a barrier-seed layer, according to various embodiments. FIG. 4 depicts examples of temperature characteristics 400 over time and relative quantities (“Qty.”) 460 of materials used over time for fabricating barrier-seed layer. In the example shown, phase C, as denoted by encircled letter C, indicates an interval of time 464 during which the barrier-seed layer is substantially formed. Further, Phase C is temporally disposed between Phase A (denoted by encircled letter A) and Phase D (denoted by encircled letter D). Phase A includes an optional time interval 461 for forming an ultrathin carbonization film, and Phase D includes an optional time interval 466 during which either a silicon carbide layer is formed at an epitaxial temperature 484, Tepi, or the deposition process is terminated.

As shown in temperature characteristics 400, the temperature can be ramped from an initial temperature, Ti, to one or more seed temperatures, Tseed, which is the temperature at which the barrier-seed layer is formed. In some embodiments, initial temperature, Ti, can be described as being equivalent to a carbonization temperature, Tc. In various examples, both the initial temperature and the carbonization temperature can be in a range between 600° C. and 850° C. In the example shown, the carbonization temperature, Tc, and the initial temperature, Ti, are approximately 750° C., according to one embodiment. In various embodiments, the seed temperature, Tseed, can range between about 800° C. and about 1,100° C., or up to 1,200° C. In one embodiment, the “seed temperature,” Tseed, can be set to approximately 1,000° C.

To illustrate the introduction of materials, consider that during interval 461 is a period of time representing the time prior barrier-seed layer formation, whereby carbon 470 is introduced to form an ultrathin carbonized film, after which an optional pump-out can occur from time, tx, to time zero, t0. During Phase B, as denoted by the encircled letter B, the temperature is modified (e.g., ramped up or down) to set the temperature from the initial temperature, Ti, to seed temperature 490, Tseed. Phase B spans interval 462 from time zero, t0, to time one, t1. In the example shown, the temperature is ramped up from 750° C. to approximately 1,000° C. In some embodiments, the ramp rate from time zero, t0, to time one, t1, is 5° C./minute. Note that in some cases, the ultrathin carbonized film is used to prevent contaminant-related defects (e.g., etch pit formation) during Phase B. Note, too, that in some cases, that the barrier-seed layer is formed to prevent contaminant-related defects (e.g., etch pit formation) during the early portions of Phase D. In some embodiments, hydrogen gas, H₂, or an inert gas can be added during the temperature ramping. In some examples, the temperature can be ramped to 1000° C. at 5° C./min in about 0.05 mbar of C₂H₂ at flow rate of 10 standard cubic centimeters per minute (“sccm”) by itself, or can be mixed with H₂ at a flow rate of 450 sccm.

During Phase C, which spans interval 464, the ratio of the two precursors of silicon-based gas 480 and carbon-based gas 482 can be two, with less than 10⁻³ mbar of total pressure of both the precursors. In some embodiments, silicon gas 480 can be introduced at a flow rate, for example, of approximately 1.5 standard cubic centimeters per minute (“sccm”), but can be at other flow rates for a particular pressure. Further, carbon gas 482 can be introduced at a flow rate, for example, of approximately 1.5 sccm, but can be at other flow rates as well for a particular pressure. In some embodiments, a region can be depressurized to a pressure that can reduce intermolecular collisions between molecules of the precursors (e.g., of the same or different precursors) and/or dopants. Thus, a precursor can be introduced during Phase C at pressures sufficient to maintain the molecular flow regime. In the molecular flow regime, the molecular mean free path can be of sufficient length to decrease collisions between gas molecules, as well as between the gas molecules and a chamber wall. In at least some embodiments, the precursor can be introduced during interval 464 at a pressure (or an approximate pressure) of 9×10⁻⁵ mbar (i.e., 0.00009 mbar), or less. In some other embodiments, precursors 480 and/or 482 can be introduced in a range of pressures including pressures of 2.3×10⁻⁵ mbar, such as a range from 1×10⁻⁵ to 9×10⁻⁴ mbar. A barrier-seed layer can be formed in Phase C at a thickness of 10 nm in about 30 minutes, according to an embodiment. In a specific embodiment, a dopant can be added to form the barrier-seed layer as a p-type barrier-seed layer.

Silicon-based gas 480 can be introduced in combination with carbon-based gas 482 into a region adjacent to a substrate to deposit a layer (e.g., a silicon carbon layer) on the substrate. Examples of silicon sources include silicon-based gases, such as silane (“SiH₄”) and other gases having the form SiₙH₂ₙ₊₂. Other examples of silicon-based gases include silicon-based gases of the form SiHₓCl_{y}, or the form SiHₓCH_{z}, or other silicon-based gases. In yet in other examples, silicon sources can include mixtures of gases, including mixtures of silicon-based gases. One example of such a mixture includes silane (“SiH₄”) and tetrachlorosilane (“SiCl₄”). Examples of carbon sources include carbon-based gases, such as hydrocarbon gases. Examples of carbon-based gases can include acetylene (e.g., C₂H₂) as well as variants thereof having the form CₓH_{2X-2}, as well as any hydrocarbon compound having the forms C_{X}H_{2X}, C_{X}H_{2X+2}, and the like.

During Phase C, according to at least some embodiments, silicon-based gas 480 and carbon-based gas 482 can be introduced in alternating fashion and/or with sequential emphasis (not shown). In some embodiments, one or more dopants can be introduced as dopant elements 483, the one or more dopants including n-type dopants or p-type dopants (e.g., during phase C or a portion thereof). An example of a p-type dopant is trimethylaluminum (“(CH₃)₃Al”), or TMAl.

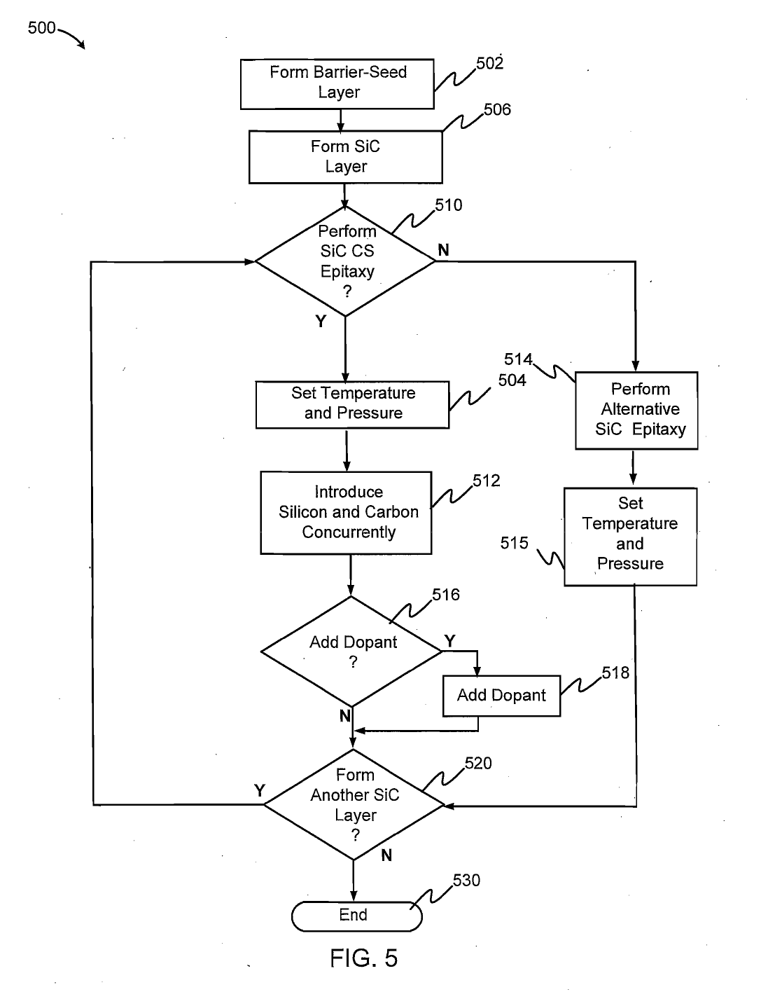

FIG. 5 is a flow diagram depicting an example of performing concurrent supply epitaxy, according to various embodiments. At 502 of flow 500, a barrier-seed layer is formed, which can be optional in some cases. At 506, a silicon carbide layer is to be formed and a determination is made at 510 as to whether to perform a silicon carbide (“SiC”) concurrent supply (“CS”) epitaxy from 504 through to 520, or to perform one of a number of alternative silicon carbide epitaxy deposition processes. If concurrent supply epitaxy is to be performed, flow 500 moves to 504 at which the fabrication parameters, including temperature and pressure, are set. At 512, silicon and carbon-based gases are introduced concurrently. A determination is made at 516 whether to form add a dopant to form a p-type silicon carbide layer or to form an n-type silicon carbide layer. At 518, a dopant is added with the silicon and carbon-based gases. For example, the dopant can be added concurrently with at least a period of time during which silicon and carbon-based gases are introduced. At 520, a determination is made whether to form another silicon carbide layer. If yes, then flow 500 returns back to 510 to select a type of epitaxy. Otherwise, flow 500 terminates at 530. If concurrent supply epitaxy is not to be performed, then flow 500 moves from 510 to 514 to perform an alternative type of silicon carbide epitaxy. One type of silicon carbide epitaxy forms an n-type silicon carbide layer by introducing either the silicon-based gas or the carbon-based gas predominantly during a first interval, and then introducing the other gas predominantly during a second interval, thereby introducing the precursors with sequential emphasis at different times. An example of this type of epitaxy is described in U.S. patent application Ser. No. 12/543,473, filed Aug. 18, 2009 with Attorney Docket No. QSS-005 and titled “Substrates and Methods of Fabricating Epitaxial Silicon Carbide Structures with Sequential Emphasis.” Another type of silicon carbide epitaxy forms a p-type silicon carbide layer by introducing either the silicon-based gas or the carbon-based gas predominantly during a first interval, and then introducing the other gas predominantly during a second interval, with p-type dopant being added by itself or along with one of the precursors. An example of this type of epitaxy is described in U.S. patent application Ser. No. 12/543,478, filed Aug. 18, 2009 with Attorney Docket No. QSS-006 and titled “Substrates and Methods of Fabricating Doped Epitaxial Silicon Carbide Structures with Sequential Emphasis.” Yet another type of silicon carbide epitaxy forms silicon carbide layers using a single precursor, SiH₃CH₃, which is methylsilane (“MS”). Other types of silicon carbide epitaxy are also possible. At 515, the fabrication parameters are set for the particular alternative SiC epitaxy determined in 514.

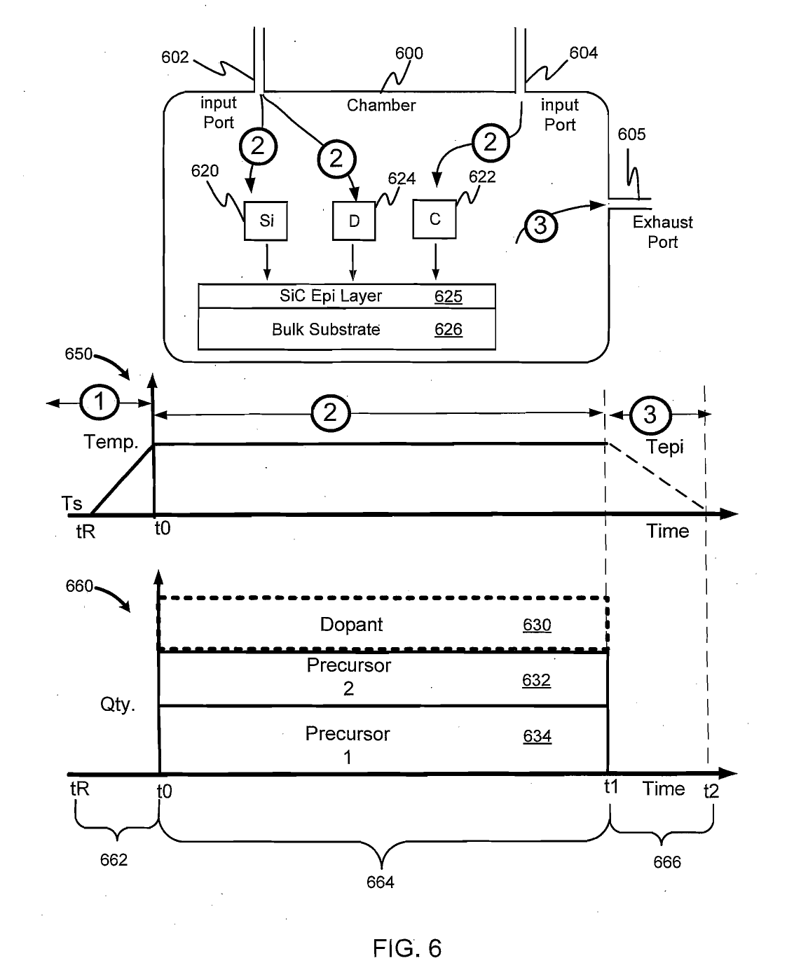

FIG. 6 is a diagram depicting an example of introducing precursors concurrently to form a silicon carbide epitaxial layer, according to various embodiments of the invention. FIG. 6 depicts examples of temperature characteristics 650 over time and quantities (“Qty.”) 660 of precursors and optional dopants over time for fabricating a silicon carbide epitaxial (“SiC Epi”) layer 625 upon a bulk substrate 626 in chamber 600. As shown in temperature characteristics 650, the temperature can be ramped from start temperature, Ts, to one or more epitaxial temperatures, Tepi, which is the temperature at which the epitaxial growth can occur. In some embodiments, start temperature, Ts, can describe the temperature prior to epitaxial growth, and the start temperature can be within the range from about 600° C. to 800° C. In other embodiments, the start temperature, Ts, can be any temperature, including an ambient temperature. In some embodiments, epitaxial temperature, Tepi, can be within the range from about 800° C. and 1300° C. For example, the epitaxial temperature can be approximately 1000° C. or 1050° C., or any temperature in between. Therefore, the surface of bulk substrate 626 and/or the interior of chamber 600 can be ramped from start temperature, Ts, to epitaxial temperature, Tepi, at a rate of about 5° C./minute from ramp time, tR, to time zero, t0, during interval 662, according to some embodiments. Interval 662 can be described as phase one, as denoted by encircled numeral 1.

To illustrate the introduction of precursors as well as the optional dopant, consider that during interval 664 a precursor (“1”) 634 are introduced via input port 602 into chamber 600 as a source of, for example, silicon (“Si”) elements 620. Further, precursor (“2”) 632 is introduced to chamber 600 concurrently with precursor 634 via input port 604 (or any other port) as a source of, for example, carbon (“C”) 622 elements. The concurrent introduction of both precursors occurs during interval 664, which can be described as phase two, as denoted by encircled numeral 2. Phase two is shown to extend from time zero, t0, to time one, t1. In some embodiments, a silicon source can be introduced at flow rates, for example, from approximately 0.05 standard cubic centimeters per minute (“sccm”) to approximately 2.0 sccm. An example of a flow rate for precursor 634 can be 1.5 sccm. In one embodiment, the flow rate at which the precursor 634 (as the silicon source) is introduced can be between 0.3 sccm and 6 sccm, or greater. In some embodiments, a precursor 632 (as the carbon source) can be introduced at flow rates, for example, from approximately 0.05 sccm to approximately 12 sccm. An example of a flow rate for precursor 632 is 1.5 sccm. In yet another example, the flow rate for precursor 632 can range from 0.05 sccm to 15 sccm, or greater. During interval 666 between time one, t1, and time two, t2, an optional pump-out operation can be performed to evacuate materials via exhaust port 605 prior to another operation, such as forming another silicon carbide layer. Note that interval 666 coincides with phase 3 (as denoted by the encircled number 3). In at least one embodiment, the silicon carbide layer can be foimed at least up to 100 nm with interval 664 extending for 30 minutes.

Note further that precursors 634 and 632 are introduced in the molecular flow regime, according to some embodiments. Note, too, that a precursor can be introduced during interval 664 at a pressure (or an approximate pressure) of 9×10⁻⁵ mbar (i.e., 0.00009 mbar), or less. In some other embodiments, precursors 632 and/or 634 can be introduced in a range of pressures including pressures of 2.3×10⁻⁵ mbar, such as a range from 1×10⁻⁵ to 9×10⁻⁴ mbar. In some embodiments, concurrent introduction of silicon-based gas and carbon-based gas forms an n-type silicon carbide layer. To form a p-type silicon carbide layer, a dopant 630 is added via an input port during interval 664 so as to be introduced concurrently with precursors 632 and 634. When forming p-type silicon carbide layers, the silicon source can be introduced at flow rates, for example, from approximately 0.05 standard cubic centimeters per minute (“sccm”) to approximately 2.0 sccm. An example of a flow rate for precursor 634 is 1.5 sccm during concurrent introduction with dopant 630, or any other flow rate between 0.5 and 2 sccm. In some embodiments, precursor 632 (as the carbon source) can be introduced at flow rates, for example, from approximately 0.05 sccm to approximately 12 sccm. In some instances, precursor 632 can be introduced at any flow rate between 0.5 and 12 sccm, or greater. An example of a flow rate for precursor 632 is approximately 0.8 sccm during concurrent introduction with dopant 630. Further, an aluminum-based dopant gas, including trimethylaluminum (“(CH₃)₃Al”), or TMAl, as well as other sources of p-type dopants can be used as dopant 630. Examples of flow rates for TMAl are from 0.05 and 0.80 sccm, up to 1.5 sccm. Dopant 630 can be introduced substantially during the molecular flow regime for the precursors and the dopant. The flow rates during interval 664 can be configured to provide concentrations of p-type carriers from 10¹⁵ to 10²⁰ per cm³ in the p-type silicon carbide epitaxial layer. In some examples, the concentrations of p-type carriers can range from 10¹⁹ to 10²⁰ per cm³.

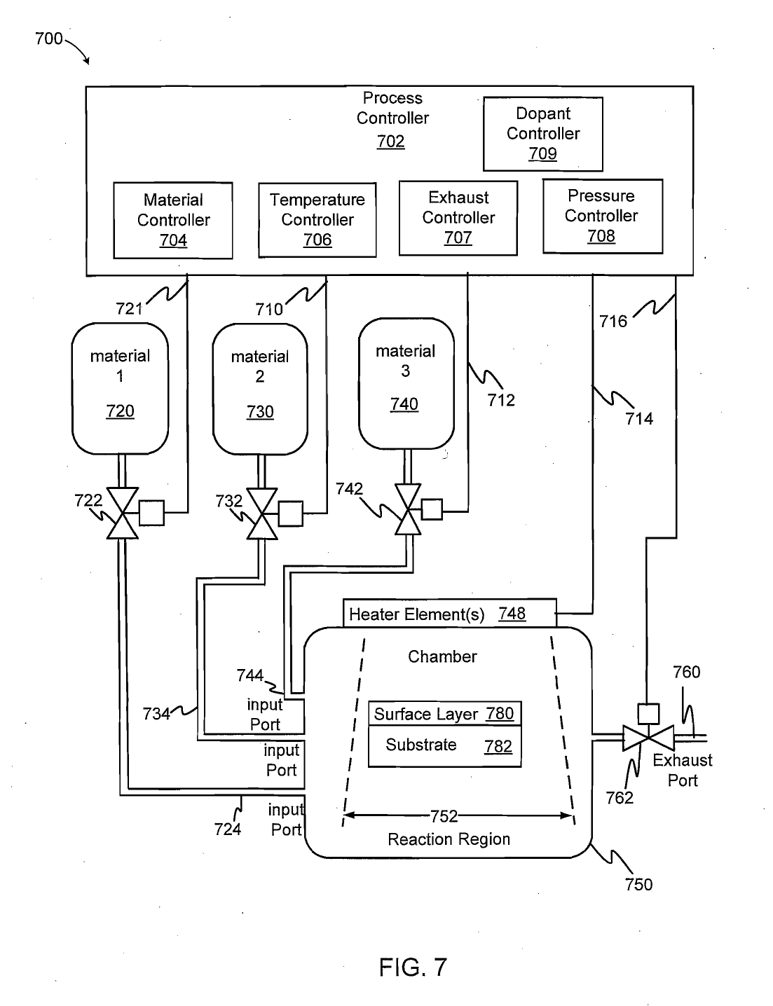

FIG. 7 illustrates a system implementing a process controller that is configured to form an ultrathin oxide, activate a substrate surface, form an ultrathin carbonized film, and/or form a barrier-seed layer, according to some embodiments. System 700 can include a process controller 702, a reservoir 720 (e.g., a gas tank) of material 1, such as oxygen gas, a reservoir 730 (e.g., a gas tank) of material 2, such as silicon gas, a reservoir 740 (e.g., a gas tank) of material 3, such as carbon gas, a heater element or elements 748, and a chamber 750, which can be configured as a tube-like structure. Note that heater element 748 is depicted as a representative mechanism by which to heat substrate 782 and/or reaction region 752 by way of, for example, infrared heating, RF heating, etc. Thus, heater element 748 need not be configured to heat the walls of chamber 750, and, as such, the walls of chamber 750 can facilitate “cold wall” wafer processing, according to some embodiments. In some embodiments, however, heater element 748 can provide for “hot wall” wafer processing. As shown, a substrate 782 (with or without a surface layer) can be disposed in a reaction region 752 at which sources of silicon, carbon, and oxygen can be introduced to form an ultrathin oxide, an activated surface, an ultrathin carbonized film, or a barrier-seed layer as surface 780.

Process controller 702 can include a material controller 704, a temperature controller 706, an exhaust controller 707, a pressure controller 708, and a dopant controller 709. Precursor controller 704 can be configured to control the introduction of the materials into chamber 750. For example, material controller 704 can transmit control signals via path 721 to control valve 722, which can open to provide oxygen as a material from reservoir 720 via input port 724 to reaction region 752. The oxygen can be used for form surface layer 780 as an ultrathin oxide. Similarly, during another interval of time, material controller 704 can transmit control signals via path 710 to control valve 732, which can open to provide silicon as a material from reservoir 730 via input port 734 to reaction region 752. The silicon can remove the ultrathin oxide and activate substrate 782 to form an activated surface as surface layer 780. Further, material controller 704 can transmit control signals via path 712 to control valve 742, which can open to provide carbon as a material from reservoir 740 via input port 744 to reaction region 752. The carbon can be used to form the ultrathin carbonized film. Also, material controller 704 can control the silicon material and carbon material to form a barrier-seed layer, according to the various embodiments. Dopant controller 709 can be configured to control the introduction of dopants into chamber 750. Dopant controller 709 can transmit control signals via a path to a control valve (not shown), which can open to provide a dopant from a reservoir (not shown) via input port 724, for example, to reaction region 752. Dopant controller 709 can be configured to control dopant introduction as a function of the type of silicon carbide epitaxy being performed (e.g., whether concurrent supply epitaxy or another type is being implemented).

Temperature controller 706 can be configured to transmit control signals via path 714 to one or more heater elements 748 to ramp up and down the temperatures, as well as to maintain various temperatures described herein. Exhaust controller 707 can be configured to transmit control signals via path 716 to control valve 762 to facilitate pumping out gaseous material or contaminants out through an exhaust port 760. In some embodiments, pressure controller 708 can be configured to maintain reaction region 752 at a relatively high vacuum to introduce materials in the molecular flow regime, and can reach relatively high pressures for introducing, for example, oxygen during formation of the ultrathin oxide. In some embodiments, a relatively high vacuum can be described by pressures (or approximate pressures) of 1×10⁻³ mbar or less, including pressures of 9×10⁻⁵ mbar (i.e., 0.00009 mbar) or less, and relatively high pressures can be described as pressures (or approximate pressures) of 0.3 mbar or greater.

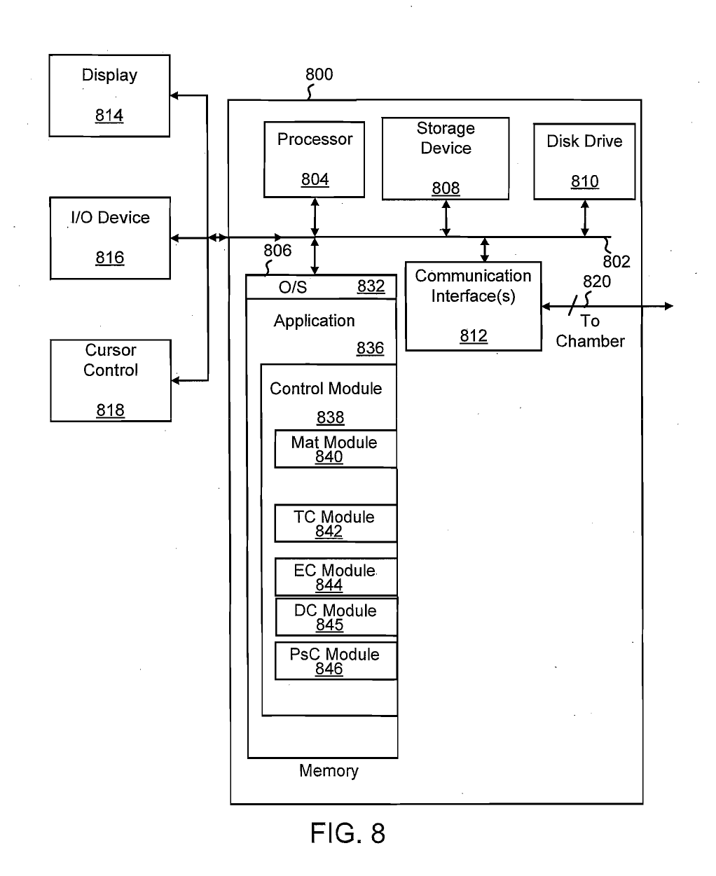

FIG. 8 illustrates an exemplary computer system suitable to form an ultrathin oxide, activate a substrate surface, form an ultrathin carbonized film, and/or form a barrier-seed layer, according to at least one embodiment. In some examples, computer system 800 can be used to implement computer programs, applications, methods, processes, or other software to perform the above-described techniques and to realize the structures described herein. Computer system 800 includes a bus 802 or other communication mechanism for communicating information, which interconnects subsystems and devices, such as one or more processors 804, system memory (“memory”) 806, storage device 808 (e.g., ROM), disk drive 810 (e.g., magnetic, optical, or solid state), communication interface 812 (e.g., a modem, Ethernet card, or any other interface configured to exchange data with a communications network or to control a fabrication machine), display 814 (e.g., CRT or LCD); input device 816 (e.g., keyboard), and pointer cursor control 818 (e.g., mouse or trackball). In one embodiment, pointer cursor control 818 invokes one or more specialized commands that can configure one or more of the following: the flow rates and the timing for the introduction of materials, the temperature characteristics (e.g., ramping up and ramping down temperatures, and maintaining a relatively quiescent temperature) during various phases of the formation of ultrathin oxide, surface activation, and/or the formation of an ultrathin carbonized film, and/or the formation of a barrier-seed layer, the pressures for various phases, and/or the rate and the timing of pumping out a chamber, as well as other parameters that can influence the flows and sub-flows described herein.

According to some examples, computer system 800 performs specific operations in which processor 804 executes one or more sequences of one or more instructions stored in system memory 806. Such instructions can be read into system memory 806 from another computer readable medium, such as static storage device 808 or disk drive 810. In some examples, hard-wired circuitry can be used in place of or in combination with software instructions for implementation. In the example shown, system memory 806 includes modules of executable instructions for implementing an operation system (“O/S”) 832, an application 836, and an epitaxy control module 838, which, in turn, can implement a material controller (“Mat Module”) module 840, a temperature controller (“TC”) module 842, an exhaust controller (“EC”) module 844, a dopant controller (“DC”) module 845, and a pressure controller (“PsC”) module 846, each of which can provide functionalities described herein.

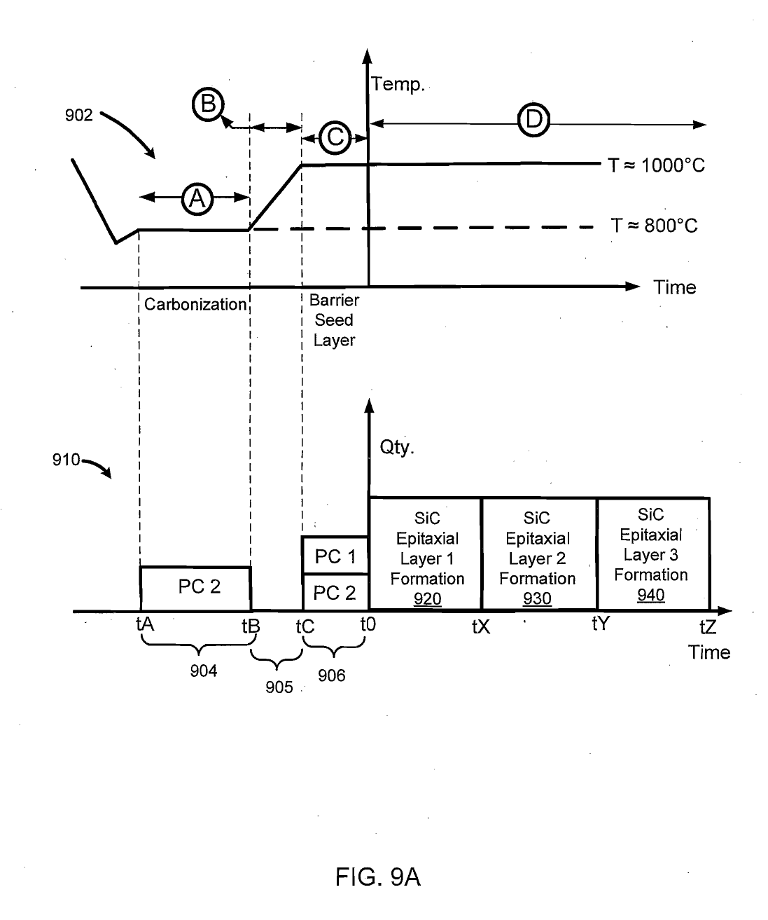

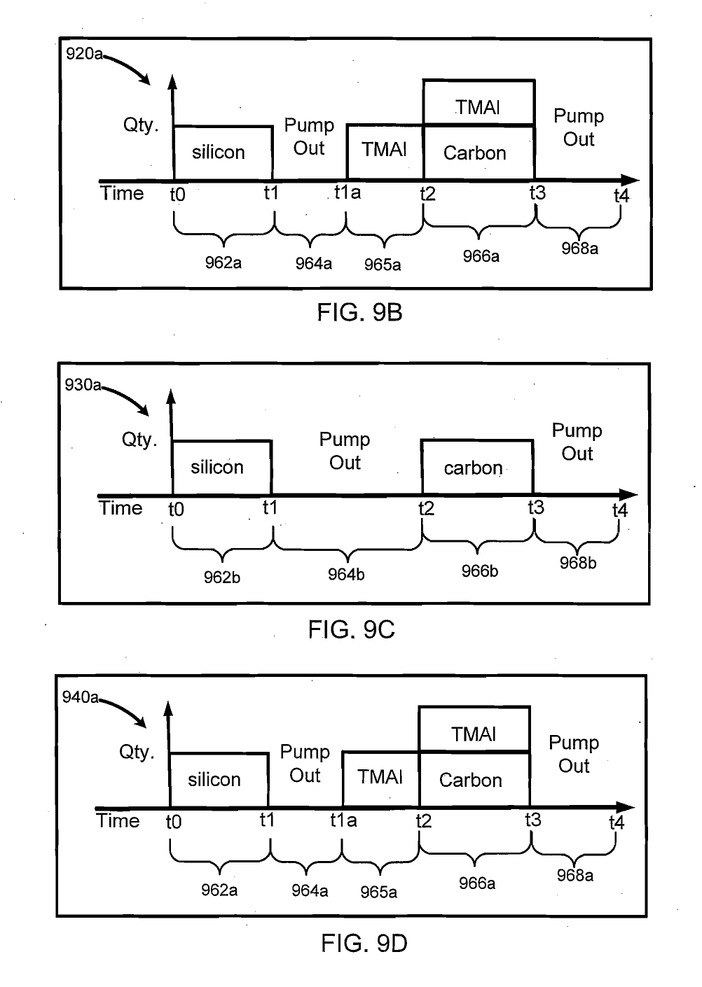

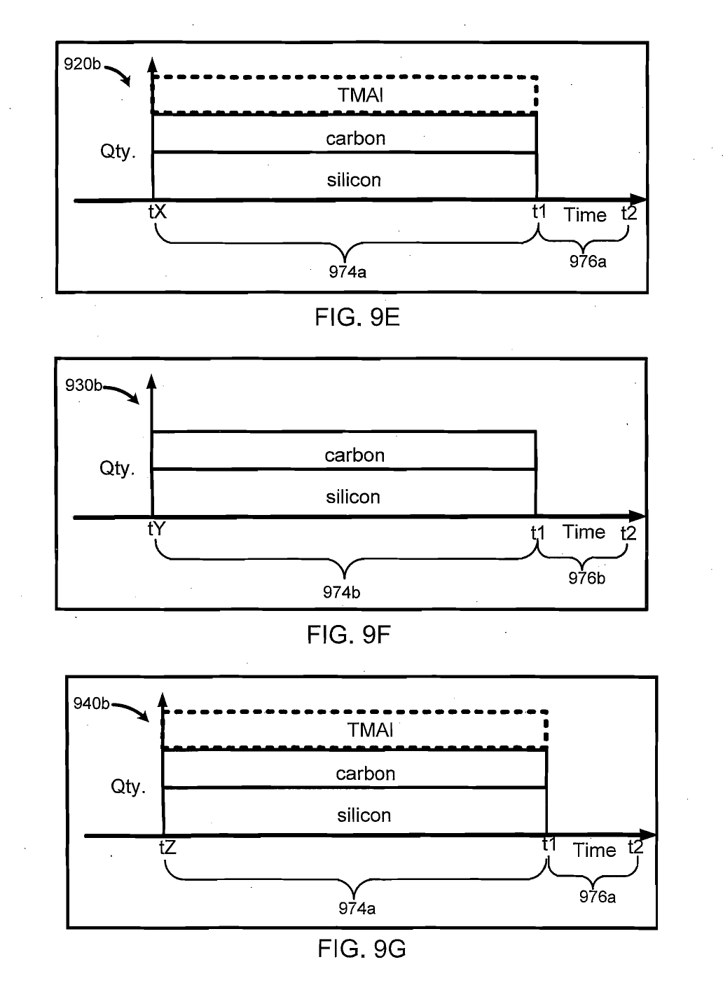

FIG. 9A is a diagram depicting another example of forming multiple layers of silicon carbide epitaxial layers and subsidiary structures, according to various embodiments of the invention. FIG. 9A depicts examples of temperature characteristics 902 over time, and quantities (“Qty.”) 910 of precursors and dopants over time to facilitate carbonization (i.e., forming a carbonized surface layer, or “an ultrathin carbonized film”) and a barrier-seed layer. As shown, the temperature can be ramped, for example, down from a temperature used to activate (e.g., clean) the surface of a substrate. For example, the temperature can be ramped down prior to time to from approximately 1000° C. to approximately 750° C. To form the ultrathin carbonized film, the temperature can be ramped to a range from approximately 750° C. to approximately 800° C., at a rate of, for example, 5° C./minute. Then, a precursor, such as precursor two (“PC2”) (e.g., source of carbon) can be introduced during interval 904 at flow rates of, for example, approximately 10 sccm, and at pressures of approximately 0.02 mbar. In some embodiments, flow rates and pressures can be within ranges (e.g., +/−20%) about 10 sccm and 0.02 mbar, respectively. In some embodiments, pressures can be above 0.02 mbar. Interval 904 can be described as phase A, as denoted by encircled letter A, and extends from time to to time tB. An example of precursor two, PC2, is acetylene (e.g., C₂H₂).

After the carbonized surface layer is formed, then the temperature can be ramped up, for example, from approximately 750° C. to approximately 1000° C. at a rate of; for example, 5° C./minute during interval 905. Interval 905 can be described as phase B, as denoted by encircled letter B, and extends from time tB to time tC. In at least one embodiment, hydrogen (“H2”) gas, nitrogen (“N2”) gas, or other suitable gases can be introduced during the ramping up of the temperature in interval 905. During interval 906 at least two precursors can be supplied concurrently to form a barrier-seed layer, according to some embodiments. Interval 906 can be described as phase C, as denoted by encircled letter C, that can extend from time tC to time t0. In some embodiments, a silicon source (“PC1”), such as SiH₄, can be introduced at a flow rate of 1.5 sccm, and a carbon source (“PC2”), such as C₂H₂, can be introduced at a flow rate of 1.5 sccm. In some embodiments, interval 906 can be approximately thirty minutes (e.g. to form the barrier-seed layer at a thickness of about 10 nm). In some embodiments, interval 906 can begin at time tB. After the barrier-seed layer is formed, then the quantities (“Qty.”) 910 of precursors and dopants, if any, over time can be supplied in a concurrent manner and/or an alternating manner, whereby the precursors can be introduced during separate intervals in a cycle.

During phase D (as denoted by the encircled letter “D”), multiple layers of silicon carbide can be formed. A first silicon carbide layer is formed during interval 920 from t0 to tX, a second silicon carbide layer is formed during interval 930 from tX to tY, and a third silicon carbide layer is formed during interval 940 from tY to tZ. In one embodiment, a silicon carbide PNP structure can be formed by forming a p-type silicon carbide layer during interval 920, an n-type silicon carbide layer during interval 930, and a p-type silicon carbide layer during interval 940. Using an epitaxy that alternates the predominance of the precursors as they are introduced, the p-type SiC layer can be formed by performing X number of cycles 920a as shown in FIG. 9B. Each cycle 920a includes introducing silicon during interval 962a, performing a pump-out during interval 964a, introducing a dopant, TMAl, during interval 965a, introducing both TMAl and carbon during interval 966a, and performing an optional pump-out during interval 968a. Cycle 920a is repeated until a desired thickness of the first p-type layer is achieved. Next, the n-type SiC layer can be formed by performing Y number of cycles 930a as shown in FIG. 9C. Each cycle 930a includes introducing silicon during interval 962b, performing a pump-out during interval 964b, introducing carbon during interval 966b, and performing an optional pump-out during interval 968b. Cycle 930a is repeated until a desired thickness of the first n-type layer is achieved. At the conclusion of interval 930 of FIG. 9A, a silicon carbide PN diode structure has been fabricated. Further, the second p-type SiC layer can be formed by performing Z number of cycles 940a as shown in FIG. 9D. Each cycle 940a includes introducing silicon during interval 962a, performing a pump-out during interval 964a, introducing a dopant, TMAl, during interval 965a, introducing both TMAl and carbon during interval 966a, and performing an optional pump-out during interval 968a. Cycle 940a is repeated until a desired thickness of the second p-type layer is achieved. At the conclusion of interval 940 of FIG. 9A, a silicon carbide PNP diode structure can be fabricated.

In one embodiment, cycles 920a and 940a each can be performed as described, for example, in U.S. patent application Ser. No. 12/543,478, filed Aug. 18, 2009, and cycle 930a can be performed as described, for example, in U.S. patent application Ser. No. 12/543,473, filed Aug. 18, 2009. According to some embodiments, the precursors and/or dopants can be introduced with “sequential emphasis,” whereby relative amounts of constituents can vary temporally, such as in an alternating or a sequential manner (e.g., a repeated sequential manner), to introduce sources of silicon and carbon, and sources of dopant. Thus, relative amounts of one or more of the constituents can predominate over one or more other constituents for an interval of time, with subsequent other constituents optionally predominating during other intervals of time. In some embodiments, a silicon carbide epitaxial layer can be formed by introducing a predominant constituent in one time interval in amounts that are greater than the other one or more constituents. In at least some embodiments, a predominant constituent can be the only constituent (e.g., approximately 100% of introduced constituent) present during an interval of time, and amounts of the one or more subordinate constituents can be absent (e.g., approximately 0% of introduced constituent) or can be substantially absent. In at least some embodiments, two constituents can be predominant over the others; that is, two constituent can be the only constituents (e.g., approximately 100% of the combined introduced constituents) present during an interval of time, and amounts of the one or more subordinate constituents can be absent (e.g., approximately 0% of introduced constituent) or can be substantially absent. For example, during an interval of time, only the carbon source and the dopant source can be introduced, whereas amounts of the silicon source during that interval can be absent.

Note that FIGS. 9A to 9D are not intended to be limiting, but rather exemplary. For example, the cycles associated with FIG. 9D can be omitted to form a PN structure using cycles in each of FIGS. 9A and 9B. Or, the cycles associated with FIG. 9C can be added after cycles of FIG. 9D to form a PNPN structure. Other variants are also possible with FIGS. 9A to 9D. For example, the fabrication techniques exemplified in one or more of FIG. 9A to 9D can be used to form NPN structures (or variants thereof), or any number of silicon carbide layers regardless of the type of dopant used. According to some embodiments, a dopant, such as TMAl, need not be introduced with any precursor and can be introduced in serial fashion.

In some embodiments, concurrent supply epitaxy can be used to form a silicon carbide PNP structure by forming a p-type silicon carbide layer during interval 920, an n-type silicon carbide layer during interval 930, and a p-type silicon carbide layer during interval 940. The p-type SiC layer formed during interval 920 by performing one cycle 920b as shown in FIG. 9E. Cycle 920b extends over interval 974a, which is substantially equivalent to interval 920 of FIG. 9A. During cycle 920b, silicon, carbon and TMAl are introduced concurrently to form the p-type SiC layer. An optional pump-out operation can be performed during interval 976a. The n-type SiC layer formed during interval 930 by performing one cycle 930b as shown in FIG. 9F Cycle 930b extends over interval 974b, which is substantially equivalent to interval 930 of FIG. 9A. During cycle 930b, silicon and carbon are introduced concurrently to form the n-type SiC layer. An optional pump-out operation can be performed during interval 976b. As depicted in FIG. 9G, the second p-type SiC layer can be formed during one or more cycles 940b similar to the first p-type SiC layer. Note that FIGS. 9A and 9E to 9G are not intended to be limiting, but rather exemplary. For example, one or more cycles associated with FIG. 9G can be omitted to form a PN structure using one or more cycles in each of FIGS. 9E and 9F. Or, one or more cycles associated with FIG. 9F can be added after the one or more cycles of FIG. 9G to form a PNPN structure. Other variants are also possible with FIGS. 9A to 9G. For example, one or more cycles associated with FIGS. 9B to 9D and one or more cycles associated with FIGS. 9E to 9G can be used together in combination in a process flow. As another example, the fabrication techniques exemplified in one or more of FIG. 9A and FIGS. 9E to 9G can be used to form NPN structures (or variants thereof), or any number of silicon carbide layers regardless of the type of dopant used. Introduction of a dopant is not limited as shown in FIGS. 9E and 9G. According to some embodiments, any dopant, such as TMAl, can be introduced during a portion of the concurrent introduction of precursors. For example, a dopant can be introduced during a portion of interval 974a of either FIG. 9E or FIG. 9G, or both. In some examples, a dopant can be introduced in a portion of interval 974a during which a precursor may or may not be absent.

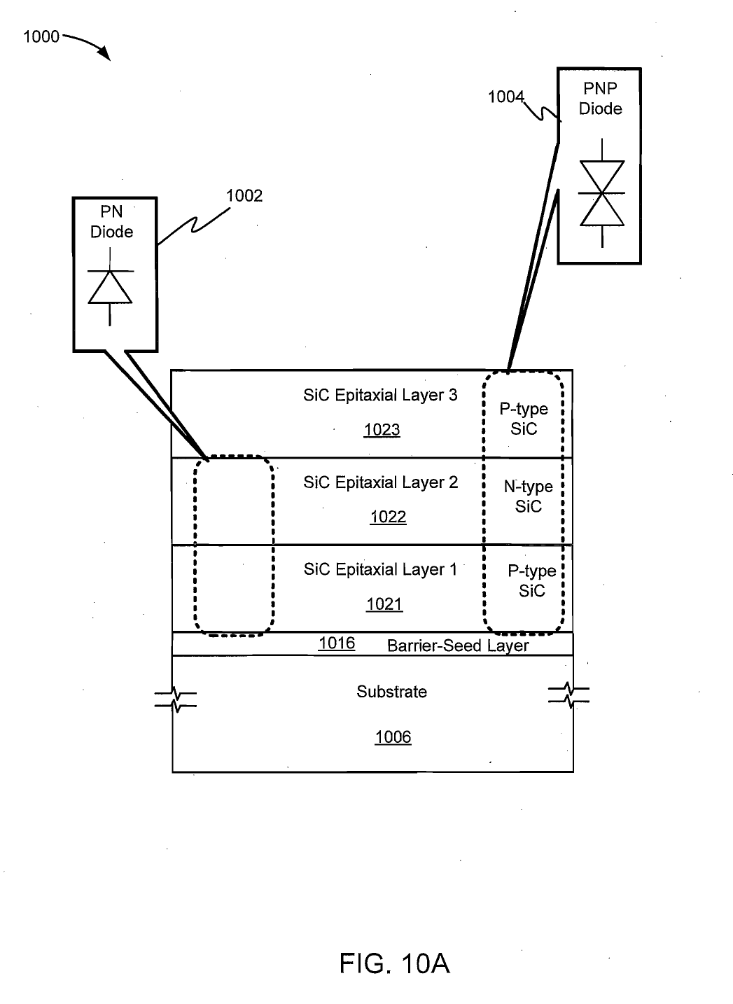

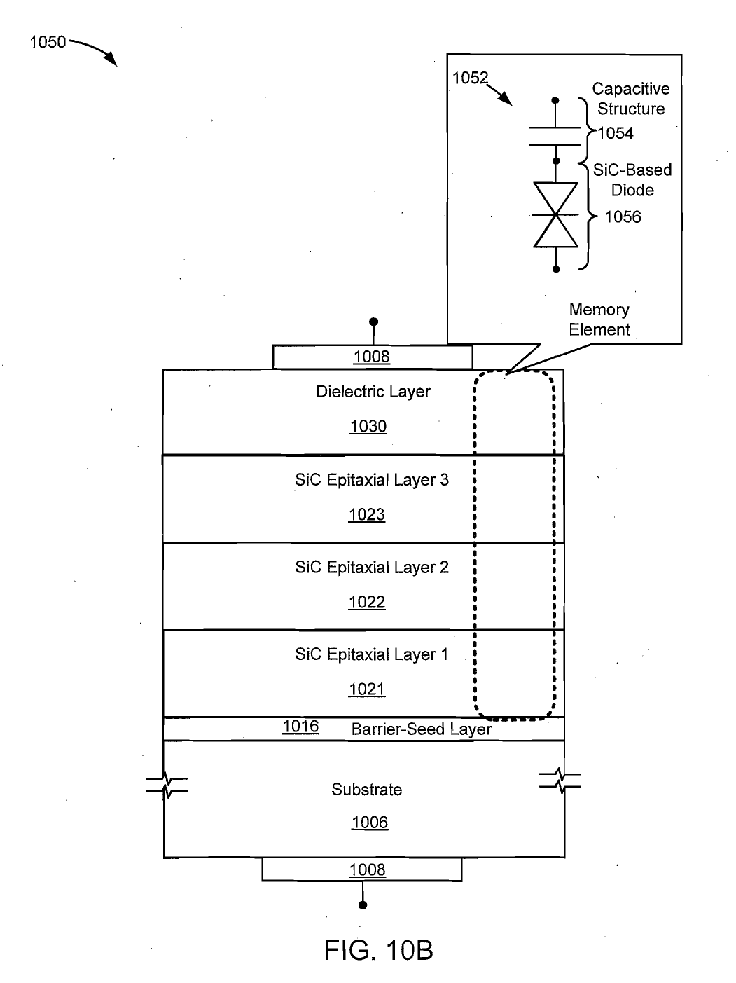

FIG. 10A is a diagram depicting a silicon carbide-based structure including multiple layers of SiC, according to various embodiments of the invention. As shown in diagram 1000, multiple layers of silicon carbide are formed on a barrier-seed layer 1016, which, in turn, is formed on a substrate 1006. In particular, the multiple layers of silicon carbide includes SiC epitaxial layer (“1”) 1021, SiC epitaxial layer (“2”) 1022, and SiC epitaxial layer (“3”) 1023. In this example, SiC epitaxial layer 1021, SiC epitaxial layer 1022, and SiC epitaxial layer 1023 include a p-type SIC layer, an n-type SiC layer, and a p-type SiC layer, respectively. Therefore, the multiple layers of silicon carbide can be used to form a silicon carbide-based PNP diode structure 1004, as well as a silicon carbide-based PN diode structure 1002, which can be fabricated, for example, without layer 1023. Note that diode 1002 can be formed using layers 1022 and 1023, in some examples.

FIG. 10B is a diagram depicting a silicon carbide-based memory element 1052 including multiple layers of SiC, according to various embodiments of the invention. As shown in diagram 1050, multiple layers of silicon carbide are formed on a barrier-seed layer 1016, which, in turn, is formed on a substrate 1006. In particular, the multiple layers of silicon carbide includes SiC epitaxial layer (“1”) 1021, SiC epitaxial layer (“2”) 1022, and SiC epitaxial layer (“3”) 1023. In this example, SiC epitaxial layer 1021, SiC epitaxial layer 1022, and SiC epitaxial layer 1023 include a p-type SiC layer, an n-type SiC layer, and a p-type SiC layer, respectively. Therefore, the multiple layers of silicon carbide can be used to form a silicon carbide-based PNP diode structure 1056. Further, a dielectric layer 1030, such as an oxide (or gate oxide) structure can be formed as a capacitive structure 1054 in series with PNP 1056.

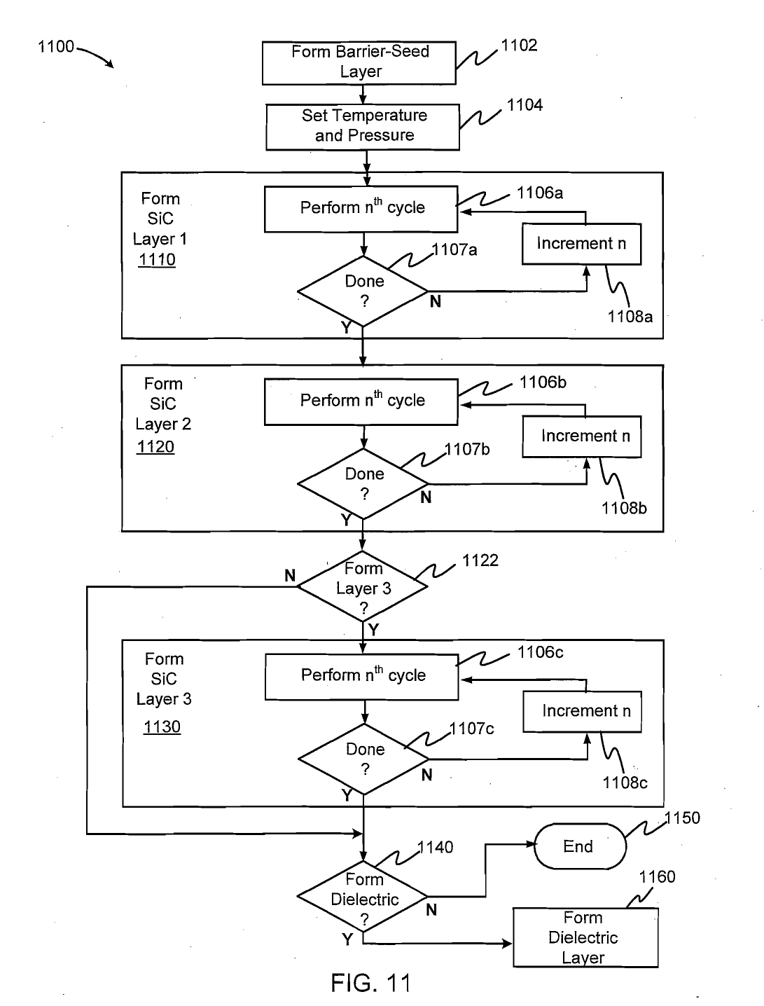

FIG. 11 is a flow diagram depicting an example of forming a silicon carbide-based memory element, according to various embodiments. At 1102 of flow 1100, a barrier-seed layer is formed, which can be optional in some cases. At 1104, fabrication parameters including temperature, pressure, flow rates, types of precursors, types of dopants, etc. are selected and/or set. A first silicon carbide layer is formed during 1110. At 1106a, an n^{th} cycle of silicon carbide deposition, according to various embodiments, is performed. At 1107a, a determination is made whether the first SiC layer is completed. If not, flow 1100 moves to 1108a to increment n, thereby indicating that flow 1100 includes performing the next (i.e., the (n+1)^{th}) cycle of silicon carbide deposition. The second SiC layer and the third SiC layer are respectively formed in 1120 and 1130 similarly to the first SiC layer. Note that at 1122, a determination is made as to whether to form a PN structure or a PNP structure (or a NPN structure). At 1140, a determination is made whether to form a dielectric layer (e.g., a SiO₂ layer). If not, then flow 1100 produces either a PN diode or a PNP/NPN diode and the flow terminates at 1150. If a dielectric layer is formed at 1160, then flow 1100 can fabricate a SiC-based memory element.

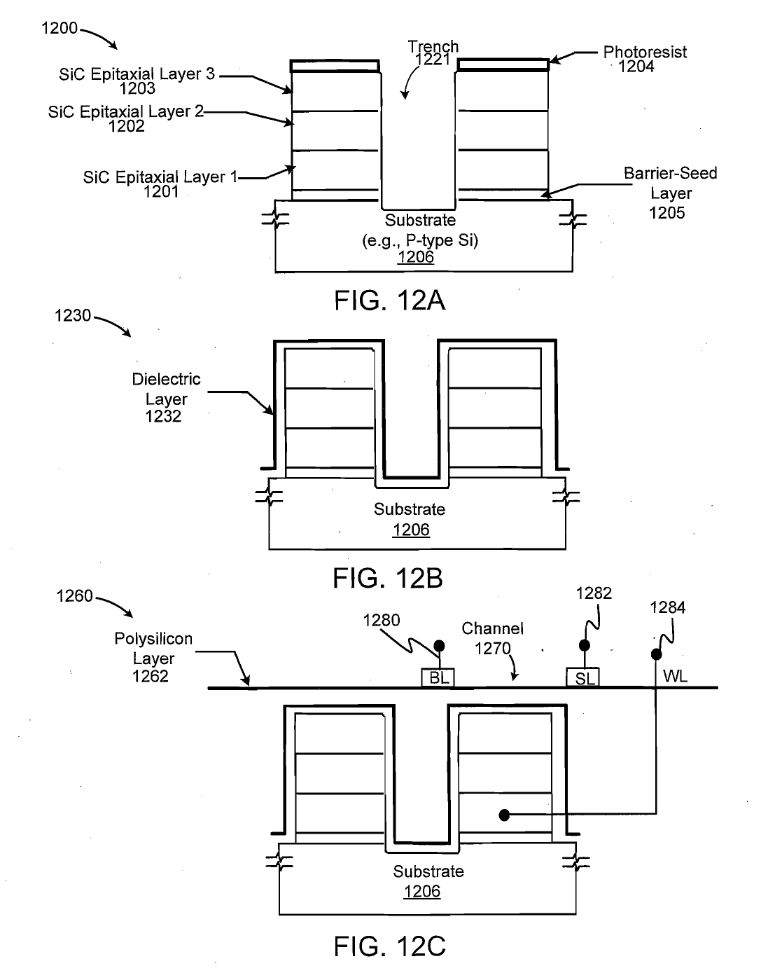

FIGS. 12A to 12C depict the fabrication of a silicon carbide-based memory element, according to various embodiments. FIG. 12A depicts a silicon carbide-based structure 1200 including multiple layers of silicon carbide (e.g., layers 1201, 1202, and 1203) formed on a barrier-seed layer 1205, which, in turn, is formed on a substrate 1206. In this example, photoresist 1204 is applied with windows exposing the SiC layers for etching through to substrate 1206 to form trench 1221. FIG. 12B depicts a silicon carbide-based structure 1230 that includes silicon carbide-based structure 1200 of FIG. 12A and a dielectric layer 1232 (e.g., a SiO₂ layer) formed over silicon carbide-based structure 1200. FIG. 12C depicts a silicon carbide-based structure 1260 that includes silicon carbide-based structure 1230 of FIG. 12B and a polysilicon layer 1262 formed over silicon carbide-based structure 1230. Further, a bit line (“BL”) terminal 1280 and a source line (“SL”) terminal 1282 are formed to establish a channel region 1270 over the top-most SiC layer. A word line (“WL”) terminal 1284 is also formed to coupled to, for example, the lower-most SiC layer. According to some embodiments, silicon carbide layer 1201 can form a word line that is configured to couple to another silicon carbide layer in another silicon carbide-based memory element (not shown), whereby the word line is composed of silicon carbide material (e.g., p-type silicon carbide material). The structures shown in FIG. 12C can constitute a SiC-based memory cell. Note that other variations and implements of SiC layers can produce a SiC-based memory element.

A silicon carbide-based memory element including a silicon substrate, a barrier-seed layer disposed over the silicon substrate, multiple silicon carbide layers formed over the barrier-seed layer, the multiple silicon carbide layers including a p-type silicon carbide layer, and an n-type silicon carbide layer, and a dielectric layer formed over the multiple silicon carbide layers. The silicon carbide-based memory element can include another p-type silicon carbide layer formed over the n-type silicon carbide layer. The silicon carbide-based memory can include a word line terminal coupled to the p-type silicon layer. The silicon carbide-based memory can include further comprising a bit line terminal and a source line terminal formed at a distance from each other to establish a channel region, the channel region being formed above the multiple silicon carbide layers. The silicon carbide-based memory including a polysilicon layer between the bit line terminal and the source line terminal and the dielectric layer, a portion of the polysilicon layer constituting the channel region. The silicon carbide-based memory can include wherein the p-type silicon carbide layer forms a word line configured to couple to another p-type silicon carbide layer in another silicon carbide-based memory element. A method of fabricating a silicon carbide-based memory element, the method including forming a barrier-seed layer over a silicon substrate, forming multiple silicon carbide layers using two separate precursors, etching through the multiple silicon carbide layers and the barrier-seed layer to at least the silicon substrate to form diode structures, depositing an oxide layer on the diode structures and forming a polysilicon layer on the oxide layer. The method of fabricating a silicon carbide-based memory can include wherein forming multiple silicon carbide layers includes depositing a first p-type silicon carbide layer on the barrier-seed layer using the two separate precursors and a dopant, depositing a first n-type silicon carbide layer on the first p-type silicon carbide layer using the two separate precursors and depositing a second p-type silicon carbide layer on the first n-type silicon carbide layer using the two separate precursors and the dopant. The method of fabricating a silicon carbide-based memory can include wherein forming the barrier-seed layer and forming the multiple silicon carbide layers includes different deposition processes. The method of fabricating a silicon carbide-based memory can include wherein forming the barrier-seed layer includes introducing a silicon-based gas substantially concurrent with introducing a carbon-based gas. The method of fabricating a silicon carbide-based memory can include wherein forming each of the multiple silicon carbide layers comprises introducing one of a silicon-based gas and a carbon-based gas predominantly during a first interval, and introducing the other of the silicon-based gas and the carbon-based gas predominantly during a second interval. The method of fabricating a silicon carbide-based memory can include further include introducing a p-type dopant during either the first interval or the second interval. The method can include wherein forming the multiple silicon carbide layers using the two separate precursors include introducing silane (“SiH4”) and acetylene (“C2H2”), respectively. The method can include wherein forming one of the multiple the silicon carbide layers using the two separate precursors comprises introducing a dopant. The method can include wherein introducing the dopant comprises introducing an aluminum-based gas. The method can include wherein forming the one of the multiple the silicon carbide layers comprises introducing silane (“SiH4”), acetylene (“C2H2”), and trimethylaluminum (“(CH3)3Al”) substantially concurrently. The method of fabricating a silicon carbide-based memory can include further comprising forming an ultrathin oxide layer, modify a temperature of a reaction region to remove the ultrathin oxide layer and to activate the surface of the silicon substrate, introducing a silicon-based gas to activate the surface of the silicon substrate, and forming an ultrathin carbonized film. The term “computer readable medium” refers, at least in one embodiment, to any medium that participates in providing instructions to processor 804 of FIG. 8 for execution. Such a medium can take many forms, including but not limited to, non-volatile media, volatile media, and transmission media. Non-volatile media includes, for example, optical or magnetic disks, such as disk drive 810. Volatile media includes dynamic memory, such as system memory 806. Transmission media includes coaxial cables, copper wire, and fiber optics, including wires that comprise bus 802. Transmission media can also take the form of electromagnetic, acoustic or light waves, such as those generated during radio wave and infrared data communications.

Common forms of computer readable media includes, for example, floppy disk, flexible disk, hard disk, magnetic tape, any other magnetic medium, CD-ROM, any other optical medium, punch cards, paper tape, any other physical medium with patterns of holes, RAM, PROM, EPROM, FLASH-EPROM, any other memory chip or cartridge, time-dependent waveforms, or any other medium from which a computer can read instructions.

In some examples, execution of the sequences of instructions can be performed by a single computer system 800. According to some examples, two or more computer systems 800 coupled by communication link 820 (e.g., links to LAN, PSTN, or wireless network) can perform the sequence of instructions in coordination with one another. Computer system 800 can transmit and receive messages, data, and instructions, including program code (i.e., application code) through communication link 820 and communication interface 812. Received program code can be executed by processor 804 as it is received, and/or stored in disk drive 810, or other non-volatile storage for later execution. In one embodiment, system 800 (or a portion thereof) can be integrated into a furnace for performing various deposition techniques, such as variants of chemical vapor deposition (“CVD”), including LPCVD, etc.

In at least some examples, the structures and/or functions of any of the above-described features can be implemented in software, hardware, firmware, circuitry, or a combination thereof. Note that the structures and constituent elements above, as well as their functionality, may be aggregated with one or more other structures or elements. Alternatively, the elements and their functionality may be subdivided into constituent sub-elements, if any. As software, the above-described techniques may be implemented using various types of programming or formatting languages, frameworks, syntax, applications, protocols, objects, or techniques. As hardware and/or firmware, the above-described techniques may be implemented using various types of programming or integrated circuit design languages, including hardware description languages, such as any register transfer language (“RTL”) configured to design field-programmable gate arrays (“FPGAs”), application-specific integrated circuits (“ASICs”), or any other type of integrated circuit. These can be varied and are not limited to the examples or descriptions provided.

The description, for purposes of explanation, uses specific nomenclature to provide a thorough understanding of the invention. However, it will be apparent that specific details are not required in order to practice the invention. In fact, this description should not be read to limit any feature or aspect of to any embodiment; rather features and aspects of one example can readily be interchanged with other examples. Notably, not every benefit described herein need be realized by each example of the invention; rather any specific example may provide one or more of the advantages discussed above. In the claims, elements and/or operations do not imply any particular order of operation, unless explicitly stated in the claims. It is intended that the following claims and their equivalents define the scope of the invention.

1. A method of fabricating one or more silicon carbide epitaxial layers on a silicon substrate, the method comprising:
forming a barrier-seed layer over the silicon substrate; and
forming a silicon carbide layer on the barrier-seed layer.

2. The method of claim 1 wherein forming the barrier-seed layer over the silicon substrate comprises:
establishing a barrier to reduce etch pit generation in the silicon substrate.

3. The method of claim 1 wherein forming the barrier-seed layer over the silicon substrate comprises:
establishing a barrier to reduce contamination of the silicon substrate.

4. The method of claim 3 wherein establishing a barrier to reduce contamination of the silicon substrate comprises:
establishing the barrier to reduce interactions between carbon elements and silicon elements in the silicon substrate.

5. The method of claim 1 further comprising:
forming the barrier-seed layer and the silicon carbide layer using a low pressure chemical vapor deposition (“LPCVD”) process.

6. The method of claim 1 wherein forming the barrier-seed layer comprises:
introducing at least two precursors into a reaction region that includes the silicon substrate differently than introducing the at least two precursors when forming the silicon carbide layer.

7. The method of claim 1 wherein forming the barrier-seed layer comprises:
introducing a silicon-based gas as a first precursor into a reaction region including the silicon substrate; and
introducing a carbon-based gas as a second precursor.

8. The method of claim 7 wherein forming the barrier-seed layer further comprises:
introducing the silicon-based gas substantially concurrent with introducing the carbon-based gas.

9. The method of claim 7 wherein forming the barrier-seed layer further comprises:
introducing a dopant.

10. The method of claim 9 wherein introducing the dopant comprises:
introducing trimethylaluminum (“(CH₃)₃Al”).

11. The method of claim 1 wherein forming the silicon carbide layer each comprises:
introducing a silicon-based gas as a first precursor into a reaction region including the silicon substrate; and
introducing a carbon-based gas as a second precursor.

12. The method of claim 11 wherein forming the silicon carbide layer further comprises:
introducing one of the silicon-based gas and the carbon-based gas predominantly during a first interval; and
introducing the other of the silicon-based gas and the carbon-based gas predominantly during a second interval.

13. The method of claim 12 further comprising:
introducing a dopant during either the first interval or the second interval.

14. The method of claim 12 further comprising:
introducing a dopant during neither the first interval nor the second interval.

15. The method of claim 11 wherein forming the silicon carbide layer further comprises:
introducing the silicon-based gas substantially concurrent with introducing the carbon-based gas to form silicon carbide layer.

16. The method of claim 15 further comprising:
introducing a dopant substantially concurrent to introducing the silicon-based gas and the carbon-based gas.

17. The method of claim 1 further comprising:
forming one or more other silicon carbide layers on the silicon carbide layer.

18. The method of claim 17 wherein forming the one or more other silicon carbide layers comprises:
forming a first silicon carbide layer as an n-type silicon carbide layer; and
forming a second silicon carbide layer as a p-type silicon carbide layer.

19. The method of claim 1 further comprising:
forming an ultrathin oxide layer;
modify a temperature of a reaction region to remove the ultrathin oxide layer and to activate the surface of the silicon substrate;
introducing a silicon-based gas to activate the surface of the silicon substrate; and
forming an ultrathin carbonized film.

20. A base wafer formed in accordance with the method of claim 1.

21. A semiconductor wafer comprising:
a silicon substrate;
a barrier-seed layer disposed over the silicon substrate; and
a silicon carbide layer formed over the barrier-seed layer.

22. The semiconductor wafer of claim 21 further comprising:
multiple silicon carbide layers including the silicon carbide layer.

23. The semiconductor wafer of claim 22 wherein at least one of the multiple silicon carbide layers comprises:
a p-type silicon carbide layer.

24. The semiconductor wafer of claim 22 wherein the multiple silicon carbide layers comprises:
a PN junction.

25. The semiconductor wafer of claim 24 further comprising:
a dielectric layer disposed over at least a portion of the multiple silicon carbide layers to form a memory element.

26. The semiconductor wafer of claim 22 wherein the multiple silicon carbide layers comprises.
a first p-type silicon carbide layer;
a first n-type silicon carbide layer formed on the first p-type silicon carbide layer; and
a second p-type silicon carbide layer formed on the first n-type silicon carbide layer.

27. The semiconductor wafer of claim 26 further comprises:
a dielectric layer disposed over at least a portion of the multiple silicon carbide layers to form a memory element.

28. The semiconductor wafer of claim 21 further comprises:
a dielectric layer disposed over at least a portion of the silicon carbide layer to form a capacitive structure.

29. A method of fabricating a silicon carbide semiconductor structure comprising:
setting the temperature of a reaction region including a substrate to a first temperature at which to form a barrier-seed layer;
introducing silicon elements into the reaction region at a first pressure;
introducing carbon elements into the reaction region concurrently with introducing the silicon elements; and
forming the barrier-seed layer over the substrate.

30. The method of claim 29 wherein introducing the silicon elements into the reaction region at the first pressure comprises:
introducing the silicon elements at a pressure indicative of a molecular flow regime.

31. The method of claim 29 further comprising
forming a silicon carbide layer over the barrier-seed layer by introducing a silicon-based gas substantially concurrent with introducing a carbon-based gas.

32. The method of claim 31 further comprising
forming the silicon carbide layer substantially at the first temperature.

33. The method of claim 29 wherein setting the temperature of the reaction region including the substrate comprises:
setting the temperature of an ultrathin carbonized film on the substrate.

34. The method of claim 33 further comprising:
ramping the temperature of the reaction region from a second temperature to first temperature; and
removing the ultrathin carbonized film prior to forming the barrier-seed layer.

35. The method of claim 29 wherein forming the barrier-seed layer comprises:
forming the barrier-seed layer to a thickness greater than 5 nm.

36. The method of claim 29 wherein setting the temperature to the first temperature comprises:
setting the temperature within a range between 800° C. and 1200° C.

37. The method of claim 29 wherein setting the temperature to the first temperature comprises:
setting the temperature within a range between 900° C. and 1100° C.

38. The method of claim 29 wherein introducing the silicon elements and introducing carbon elements comprises:
introducing silane (“SiH₄”) and acetylene (“C₂H₂”), respectively.

39. The method of claim 29 further comprising:
introducing trimethylaluminum (“(CH₃)₃Al”) as a dopant.
